(19) United States
(12) Patent Application Publication
(10) Pub. No.: US 2019/0081173 A1
(43) Pub. Date: Mar. 14, 2019

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Tatsuya NISHIWAKI, Nonoichi Ishikawa (JP); Kentaro ICHINOSEKI, Nonoichi Ishikawa (JP); Kikuo AIDA, Nomi Isikawa (JP); Kohei OASA, Nonoichi Ishikawa (JP); Hung HUNG, Kawasaki Kanagawa (JP); Hiroshi MATSUBA, Kanazawa Ishikawa (JP)

(21) Appl. No.: 15/903,955

(22) Filed: Feb. 23, 2018

(30) Foreign Application Priority Data
Sep. 14, 2017 (JP) 2017-176264

(51) Int. Cl. H01L 29/78; H01L 29/40; H01L 29/06

(52) U.S. Cl. CPC H01L 29/7813; H01L 29/0615; H01L 29/407

(57) ABSTRACT

A semiconductor device which includes a semiconductor layer, a first electrode, a second electrode, first trenches, a second trench surrounding the first trenches, a gate electrode and a first field plate electrode in the first trenches, a first insulating layer including a first portion p having a first film thickness, a second portion having a second film thickness thicker than the first film thickness, and a third portion having a third film thickness thicker than the second film thickness, a second field plate electrode in the second trench, a second insulating layer in the second trench. The semiconductor layer includes a first semiconductor region having a first conductivity type, a second semiconductor region having a second conductivity type, and a third semiconductor region having the second conductivity type.

### CROSS-REFERENCE TO RELATED APPLICATION

This application is based upon and claims the benefit of priority from Japanese Patent Application No. 2017-176264, filed Sep. 14, 2017, the entire contents of which are incorporated herein by reference.

### FIELD

Embodiments described herein relate generally to a semiconductor device.

### BACKGROUND

As an example of a power semiconductor device, there is a vertical transistor device, such as a metal oxide field effect transistor (MOSFET) or an insulated gate bipolar transistor (IGBT) , having a trench gate structure in which a gate electrode is provided in a trench formed in a semiconductor layer. The gate electrode is provided in the trench so as to make it possible to improve a degree of integration and to increase the on-current of the vertical transistor.

In order to improve a breakdown voltage of a vertical transistor having the trench gate structure, a trench field plate structure can be adopted. In the trench field plate structure, a field plate electrode separated by an insulating film is provided below the gate electrode in the trench to control electric field distribution in the semiconductor layer and to improve the breakdown voltage of the vertical transistor.

At terminal end portions of the trench, an electric field in the semiconductor layer is structurally concentrated, and avalanche breakdown may occur at a relatively low voltage at these points. For that reason, there is a problem that the breakdown voltage of the vertical transistor can be deteriorated due to the terminal end effects.

### DESCRIPTION OF THE DRAWINGS

FIG. 1 is a schematic plan view of a semiconductor device of a first embodiment.

FIG. 2 is a schematic plan view of a portion of the semiconductor device of the first embodiment.

FIGS. 3A and 3B are schematic cross-sectional views of the portion of the semiconductor device of the first embodiment.

FIG. 4 is another schematic cross-sectional view of the portion of the semiconductor device of the first embodiment.

FIG. 5 is a schematic cross-sectional view and an electric field distribution diagram of a semiconductor device of a first comparative example.

FIG. 6 is a schematic cross-sectional view and an electric field distribution diagram of a semiconductor device of a second comparative example.

FIG. 7 is a schematic plan view of the semiconductor device according to the first and second comparative examples.

FIG. 8 is a schematic plan view of a portion of the semiconductor device according to the first and second comparative examples.

FIG. 9 is a schematic cross-sectional view of the portion of the semiconductor device of the first comparative example.

FIG. 10 is a schematic cross-sectional view of the portion of the semiconductor device of the second comparative example.

FIG. 11 is a schematic plan view and an electric field distribution diagram of the semiconductor device of the first comparative example.

FIG. 12 is a schematic plan view and an electric field distribution diagram of the semiconductor device of the second comparative example.

FIGS. 13A to 13C are schematic cross-sectional views of a portion of a semiconductor device according to a modification example of the first embodiment.

FIG. 14 is a schematic cross-sectional view of a portion of a semiconductor device of a second embodiment.

FIG. 15 is a schematic plan view of a portion of the semiconductor device of a third embodiment.

FIG. 16 is a schematic plan view of a portion of the semiconductor device of a fourth embodiment.

FIG. 17 is a schematic plan view of a semiconductor device according to a fifth embodiment.

FIG. 18 is a schematic plan view of a portion of the semiconductor device of the fifth embodiment.

FIG. 19 is a schematic plan view of a semiconductor device according to a sixth embodiment.

FIG. 20 is a schematic plan view of a portion of the semiconductor device of the sixth embodiment.

FIG. 21 is a schematic plan view of a semiconductor device of a seventh embodiment.

FIG. 22 is a schematic plan view of the semiconductor device of an eighth embodiment.

FIG. 23 is a schematic plan view of a portion of the semiconductor device of the eighth embodiment.

FIGS. 24A and 24B are schematic cross-sectional views of the portion of the semiconductor device of the eighth embodiment.

FIG. 25 is another schematic cross-sectional view of the portion of the semiconductor device of the eighth embodiment.

FIG. 26 is a schematic plan view and an electric field distribution diagram of the semiconductor device of the eighth embodiment.

FIG. 27 is a schematic cross-sectional view of a portion of a semiconductor device of a ninth embodiment.

### DETAILED DESCRIPTION

In general, according to one embodiment, a semiconductor device includes a semiconductor layer having a first surface and a second surface opposite the first surface. A first electrode contacts the first surface. A second electrode contacts the second surface. A plurality of first trenches are in the semiconductor layer. Each first trench is extending longitudinally in a first direction that is substantially parallel to the first surface, is spaced from an adjacent first trench in the plurality of first trenches in a second direction crossing the first direction and substantially parallel to the first direction, and is extending into the semiconductor layer along a third direction substantially orthogonal to the first surface. A second trench is in the semiconductor layer and surrounding the plurality of first trenches within a plane substantially parallel to the first surface. A first gate electrode is in each first trench of the plurality of first trenches. A first field plate electrode is also in each first trench of the plurality of first trenches, between the first gate electrode and the second surface in the third direction. A first insulating layer includes a first portion of a first film thickness in each first trench of the plurality of first trenches between the first gate electrode and the semiconductor layer; a second portion of a second film thickness in each first trench of the plurality of first trenches between the first field plate electrode and the semiconductor layer, the second film thickness being greater than the first film thickness; and a third portion of a third film thickness in each first trench of the plurality of first trenches between the second portion and the second surface, the third film thickness being greater than the second film thickness. A second field plate electrode is in the second trench. A second insulating layer is in the second trench between the second field plate electrode and the semiconductor layer. A first semiconductor region of the semiconductor layer has a first conductivity type and is between two adjacent first trenches of the plurality of first trenches. A second semiconductor region of the semiconductor layer has a second conductivity type and is between the first semiconductor region and the second surface along the third direction. A third semiconductor region of the semiconductor layer has the second conductivity type and is between the first semiconductor region and the first electrode along the third direction and is electrically connected to the first electrode.

Hereinafter, example embodiments will be described with reference to the drawings. In the following description, the same or similar components and the like are denoted by the same reference numerals, and description of the components and the like that have been described previously may be appropriately omitted.

In the present specification, when there are written notations of n⁺-type, n-type and n⁻-type, it means that n-type impurity concentration is lowered in an order of the n⁺-type, n-type, and n⁻-type. In addition, when there are written notations of p⁺-type, p-type, and p⁻-type, it means that p-type impurity concentration is lowered in an order of the p⁺-type, p-type, and p⁻-type.

### First Embodiment

A semiconductor device of a first embodiment includes: a semiconductor layer having a first surface and a second surface which is opposite the first surface; a first electrode in contact with the first surface; a second electrode in contact with the second surface; a plurality of first trenches provided in the semiconductor layer and extending in a first direction substantially parallel to the first surface; a second trench provided in the semiconductor layer and surrounding the plurality of first trenches; a gate electrode provided in each of the plurality of first trenches; a first field plate electrode provided in each of the plurality of first trenches to be between the gate electrode and the second surface; a first insulating layer including a first portion in each of the plurality of first trenches, located between the gate electrode and the semiconductor layer, and having a first film thickness, a second portion located between the first field plate electrode and the semiconductor layer and having a second film thickness thicker than the first film thickness, a third portion located between the second portion and the second surface and having a third film thickness thicker than the second film thickness; a second field plate provided in the second trench; a second insulating layer provided in the second trench to be between the second field plate electrode and the semiconductor layer; a first semiconductor region having a first conductivity type provided in the semiconductor layer and located between two adjacent first trenches of the plurality of first trenches; a second semiconductor region having a second conductivity type provided in the semiconductor layer and located between the first semiconductor region and the second surface; and a third semiconductor region having the second conductivity type provided in the semiconductor layer, located between the first semiconductor region and the first electrode, and electrically connected to the first electrode.

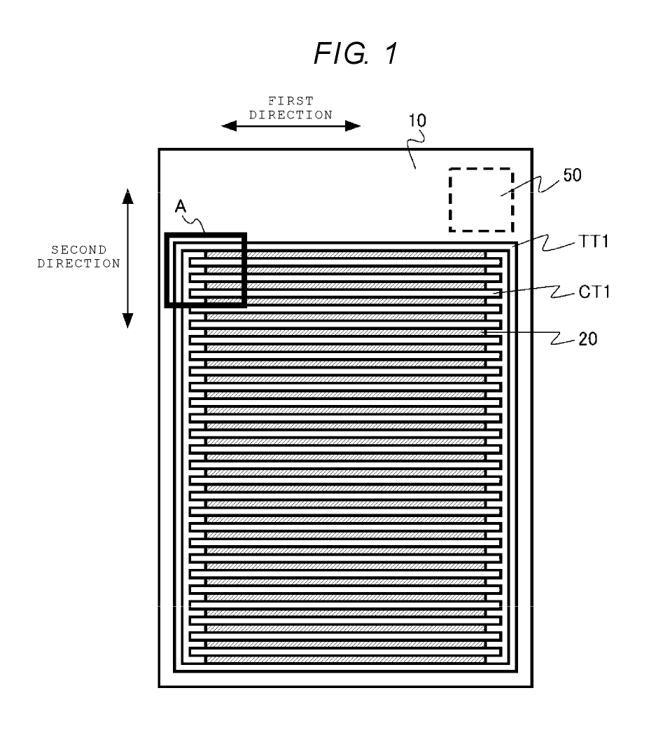

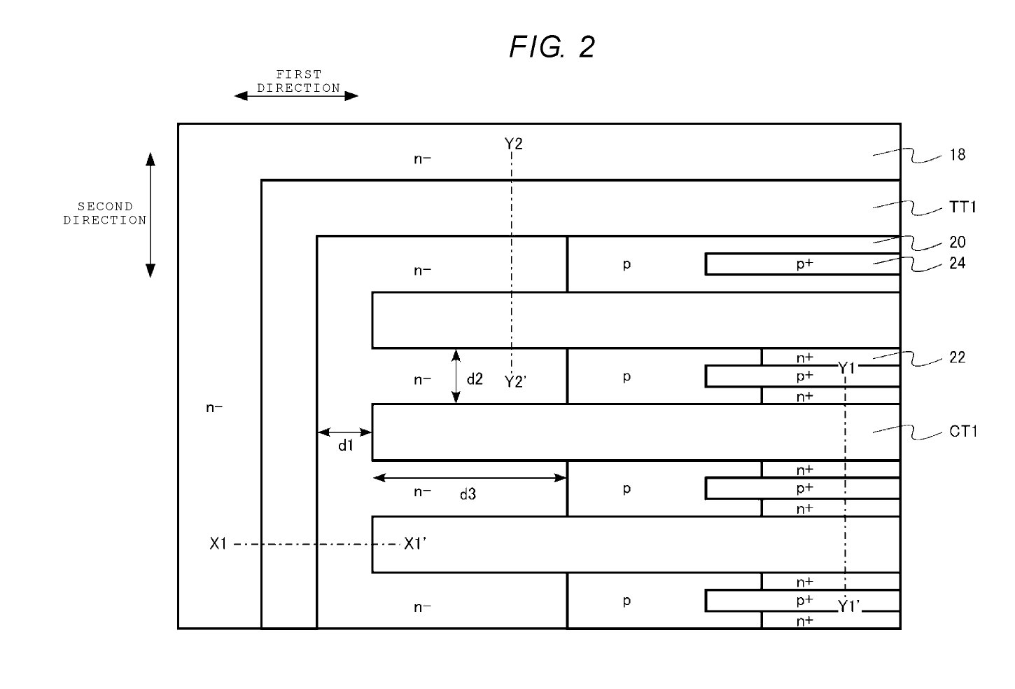

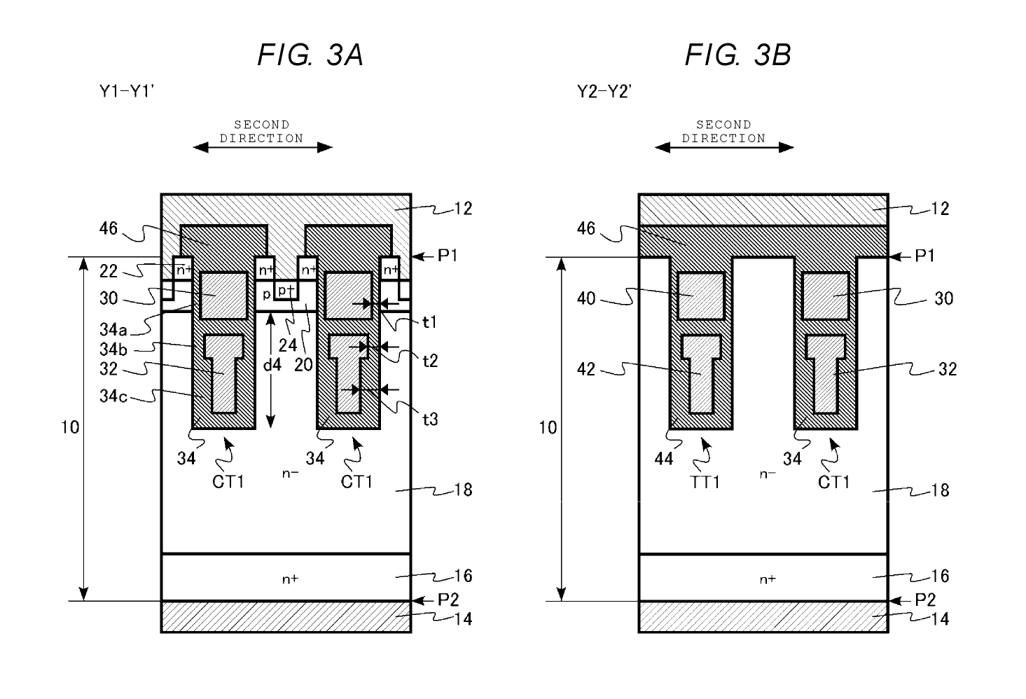

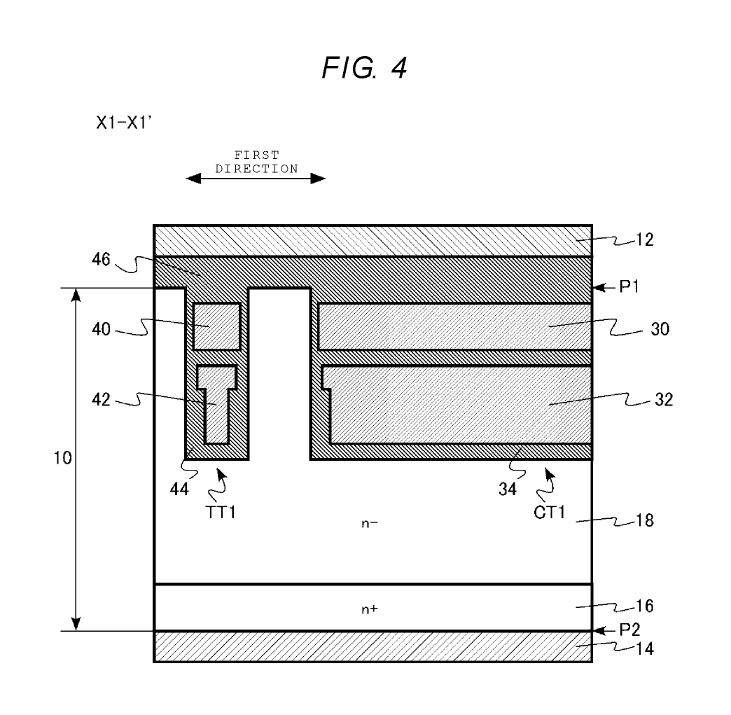

FIG. 1 is a schematic plan view of a semiconductor device of a first embodiment. FIG. 2 is a schematic plan view of a portion of the semiconductor device of the first embodiment. FIG. 2 is a schematic plan view of a portion surrounded by a frame line A in FIG. 1. FIGS. 3A and 3B are schematic cross-sectional views of a portion of the semiconductor device of the first embodiment. FIG. 3A is a cross section taken along line Y1-Y1′ of FIG. 2, and FIG. 3B is a cross section taken along line Y2-Y2′ of FIG. 2. FIG. 4 is another schematic cross-sectional view of the portion of the semiconductor device of the first embodiment. FIG. 4 is a cross-sectional view taken along the line X1-X1′ of FIG. 2.

The semiconductor device of the first embodiment is a vertical MOSFET having a vertical trench gate structure in which a gate electrode is provided in a trench formed in a semiconductor layer. The vertical MOSFET of the first embodiment also has a trench field plate structure. The vertical MOSFET of the first embodiment is an n-channel type transistor using electrons as carriers.

The vertical MOSFET of the first embodiment includes a semiconductor layer 10, a cell trench CT1, a termination trench TT1, a source electrode 12, a drain electrode 14, a drain region 16, a drift region 18,a base region 20, a source region 22, abase contact region 24, a cell gate electrode 30, a cell field plate electrode 32, a cell trench insulating layer 34, a termination gate electrode 40, a termination field plate electrode 42, a termination trench insulating layer 44, and an interlayer insulating layer 46. The cell trench insulating layer 34 includes a gate insulating film 34a, an upper field plate insulating film 34b, and a lower field plate insulating film 34c. The vertical MOSFET of the first embodiment has a gate pad electrode 50.

FIG. 1 schematically illustrates a layout of cell trenches CT1, the termination trench TT1, the base region 20, and the gate pad electrode 50. The cell trenches CT1 and the termination trench TT1 are provided in the semiconductor layer 10.

The semiconductor layer 10 has a first surface P1 (hereinafter, also referred to as a front surface) and a second surface P2 (hereinafter, also referred to as a rear surface) which is opposite the first surface P1. The semiconductor layer 10 is, for example, single crystal silicon. A film thickness of the semiconductor layer 10 is, for example, between 50 μm and 300 μm.

The plurality of cell trenches CT1 extend in the first direction. The first direction is substantially parallel to a front surface of the semiconductor layer 10. The plurality of cell trenches CT1 are arranged at substantially regular intervals in a second direction orthogonal to the first direction.

The termination trench TT1 surrounds the plurality of cell trenches CT1. The plurality of cell trenches CT1 are provided inside the region surrounded by termination trench TT1. The termination trench TT1 and the cell trenches CT1 are provided apart from each other at a predetermined distance.

The plurality of cell trenches CT1 and the termination trench TT1 can be simultaneously formed in the semiconductor layer 10 by, for example, a dry etching technique.

The gate pad electrode 50 is provided on a region outside that surrounded by the termination trench TT1.

At least a portion of the source electrode 12 is in contact with a first surface P1 of the semiconductor layer 10. The source electrode 12 is, for example, metal. A source voltage is applied to the source electrode 12. The source voltage is, for example, 0 V.

At least a portion of the drain electrode 14 is in contact with a second surface P2 of the semiconductor layer 10. The drain electrode 14 is, for example, metal. A drain voltage is applied to the drain electrode 14. The drain voltage is, for example, between 200 V and 1500 V.

A cell gate electrode 30 is provided in each of the plurality of cell trenches CT1. The cell gate electrode 30 is, for example, polycrystalline silicon containing n-type impurities or p-type impurities.

A gate voltage is applied to the cell gate electrode(s) 30. By changing the gate voltage, an ON/OFF switching operation of the vertical MOSFET 100 is realized.

A cell field plate electrode 32 is provided in each of the plurality of cell trenches CT1. The cell field plate electrode 32 is provided between the cell gate electrode 30 and a rear surface of the semiconductor layer 10. The cell field plate electrode 32 is, for example, polycrystalline silicon containing n-type impurities or p-type impurities.

A width of an upper portion of the cell field plate electrode 32 in the second direction is wider than the width of a lower portion of the cell field plate electrode 32 in the second direction. The vertical MOSFET of the first embodiment has a so-called “two-stage field plate structure” in which the width of the cell field plate electrode 32 changes in two stages along the depth direction.

For example, a source voltage is applied to the cell field plate electrode 32. A configuration in which the gate voltage is applied to the cell field plate electrode 32 is also possible.

The cell gate electrode 30 and the cell field plate electrode 32 are surrounded by the cell trench insulating layer 34. The cell trench insulating layer 34 includes the gate insulating film 34a, the upper field plate insulating film 34b, and the lower field plate insulating film 34c. The cell trench insulating layer 34 is, for example, silicon oxide. The gate insulating film 34a, the upper field plate insulating film 34b, and the lower field plate insulating film 34c may be formed in the same process, or portions thereof may also be formed in separate processes.

The gate insulating film 34a is located between the cell gate electrode 30 and the semiconductor layer 10. The gate insulating film 34a has a first film thickness t1.

The upper field plate insulating film 34b is located between the upper portion of the cell field plate electrode 32 and the semiconductor layer 10. The upper field plate insulating film 34b has a second film thickness t2.

The lower field plate insulating film 34c is located between the lower portion of the cell field plate electrode 32 and the semiconductor layer 10. The lower field plate insulating film 34c is located between the upper field plate insulating film 34b and the rear surface of the semiconductor layer 10. The lower field plate insulating film 34c has a third film thickness t3.

The second film thickness t2 of the upper field plate insulating film 34b is thicker than the first film thickness t1 of the gate insulating film 34a. The third film thickness t3 of the lower field plate insulating film 34c is thicker than the second film thickness t2 of the upper field plate insulating film 34b.

For example, after an insulating film is formed on the inner surface of the cell trench CT1, a portion corresponding to the lower field plate insulating film 34c can be covered with a masking material and the unmasked portions of the insulating film can be etched to be thinned so as to make it possible to form the upper field plate insulating film 34b. As the masking material, for example, polycrystalline silicon or photoresist can be applied.

The second film thickness t2 of the upper field plate insulating film 34b is, for example, between 40% to 60% of the third film thickness t3.

The termination gate electrode 40 is provided in the termination trench TT1. The termination gate electrode 40 is, for example, polycrystalline silicon containing n-type impurities or p-type impurities.

The termination gate electrode 40 does not particularly contribute to the ON/OFF switching operation of the vertical MOSFET. For example, a source voltage can be applied to the termination gate electrode 40. A configuration in which the gate voltage is applied to the termination gate electrode 40 is also possible.

The termination field plate electrode 42 is provided in the termination trench TT1. The termination field plate electrode 42 is provided between the termination gate electrode 40 and the rear surface of the semiconductor layer 10. The termination field plate electrode 42 is, for example, polycrystalline silicon containing n-type impurities or p-type impurities.

The width of the upper portion of the termination field plate electrode 42 in the second direction is wider than the width of the lower portion of the termination field plate electrode 42 in the second direction.

The termination gate electrode 40 and the termination field plate electrode 42 are surrounded by the termination trench insulating layer 44. The termination trench insulating layer 44 is, for example, silicon oxide. In the termination trench insulating layer 44 between the termination field plate electrode 42 and the semiconductor layer 10, a portion is thin and a portion is thicker than the thin portion. The thick portion is at a position deeper into the semiconductor layer 10 than the thin portion. A film thickness of the thin portion may be referred to as a fourth film thickness and a film thickness of the thick portion may be referred to as a fifth film thickness.

The base region 20 is provided in the semiconductor layer 10. The base region 20 is located between two adjacent cell trenches CT1. The base region 20 is a p-type semiconductor region. A region of the base region 20 in contact with the gate insulating film 34a functions as a channel region of the vertical MOSFET 100. The base region 20 is electrically connected to the source electrode 12.

The source region 22 is provided in the semiconductor layer 10. The source region 22 is provided between the base region 20 and the front surface of the semiconductor layer 10. The source region 22 is provided between the base region 20 and the source electrode 12. The source region 22 is an n-type semiconductor region. The source region 22 is electrically connected to the source electrode 12.

The base contact region 24 is provided in the semiconductor layer 10. The base contact region 24 is provided between the base region 20 and the source electrode 12. The base contact region 24 is a p-type semiconductor region. P-type impurity concentration of the base contact region 24 is higher than the p-type impurity concentration of the base region 20. The base contact region 24 is electrically connected to the source electrode 12.

The drift region 18 is provided in the semiconductor layer 10. The drift region 18 is provided between the base region 20 and the rear surface of the semiconductor layer 10. The drift region 18 is an n-type semiconductor region. N-type impurity concentration of the drift region 18 is lower than n-type impurity concentration of the source region 22.

The drain region 16 is provided in the semiconductor layer 10. The drain region 16 is provided between the drift region 18 and the rear surface of the semiconductor layer 10. The drain region 16 is an n-type semiconductor region. The n-type impurity concentration of the drain region 16 is higher than the n-type impurity concentration of the drift region 18. The drain region 16 is electrically connected to the drain electrode 14.

The gate pad electrode 50 is provided on the semiconductor layer 10. The gate pad electrode 50 is provided on the side of the front surface of the semiconductor layer 10. The gate pad electrode 50 is electrically connected to at least the cell gate electrode 30. The gate pad electrode 50 is, for example, metal.

FIG. 2 illustrates a layout of the cell trench CT1, the termination trench TT1, the drain region 16, the drift region 18, the base region 20, the source region 22, and the base contact region 24, on the front surface of the semiconductor layer 10, of a portion surrounded by the frame line A of FIG. 1.

As illustrated in FIG. 1 and FIG. 2, the base region 20 is not present between the end portion of the cell trench CT1 and the termination trench TT1, and also is not present in the vicinity of the end portion of the cell trench CT1.

For example, a first distance (e.g., d1 in FIG. 2) between the end portion of the cell trench CT1 and the termination trench TT1 is smaller than a second distance between two adjacent cell trenches CT1 (e.g., d2 in FIG. 2). The first distance d1 is, for example, 90% or less of the second distance d2.

For example, a distance (e.g., d3 in FIG. 2) between the end portion of the cell trench CT1 and the end portion of the base region 20 is greater than or equal to a distance (e.g., d4 in FIG. 3A) between the base region 20 and the bottom portion on the side of the rear surface of the semiconductor layer 10 of the cell trench CT1.

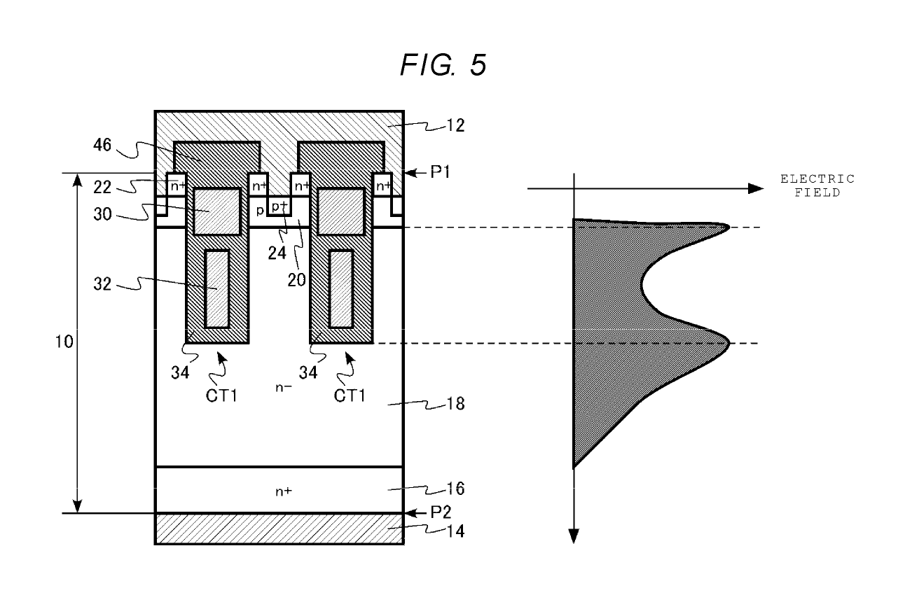

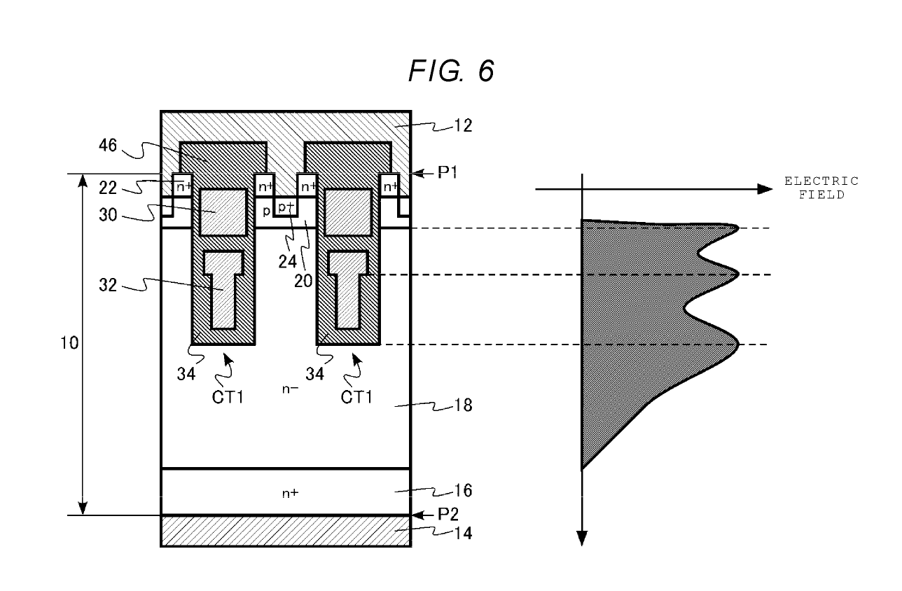

An effect of the two-stage field plate structure will be described. FIG. 5 and FIG. 6 are explanatory diagrams for the effect of field plate structure.

FIG. 5 is a schematic sectional view and an electric field distribution diagram of a semiconductor device according to the first comparative example. The semiconductor device of the first comparative example is a vertical MOSFET. FIG. 5 illustrates a cross section of the cell trench CT1 in the first comparative example. The cross section depicted in FIG. 5 is a cross section corresponding to the cross section depicted in FIG. 3A. The vertical MOSFET of the first comparative example has a one-stage field plate structure.

FIG. 6 is a schematic cross-sectional view and an electric field distribution diagram of a semiconductor device of a second comparative example. The semiconductor device of the second comparative example is a vertical MOSFET. FIG. 6 illustrates a cross section of the cell trench CT1 of the second comparative example. The cross section depicted in FIG. 6 corresponds to the cross section depicted in FIG. 3A. The vertical MOSFET of the second comparative example has a two-stage field plate structure.

In the one-stage field plate structure illustrated in FIG. 5, the width of the cell field plate electrode 32 is substantially constant and there is no step in the cell field plate electrode 32. The film thickness of the cell trench insulating layer 34 between the cell field plate electrode 32 and the semiconductor layer 10 is also substantially constant. The breakdown voltage of the vertical MOSFET is improved by increasing an integrated value of the electric field in the depth direction. In the one-stage field plate structure, a peak of an electric field strength is generated at the bottom of the cell trench CT1 so that the breakdown voltage of the vertical MOSFET is improved.

In the two-stage field plate structure illustrated in FIG. 6, a width of the upper portion of the cell field plate electrode 32 is wider than a width of the lower portion thereof. In the two-stage field plate structure, the width of the cell field plate electrode 32 changes in a stepwise manner. The film thickness of the cell trench insulating layer 34 between the cell field plate electrode 32 and the semiconductor layer 10 also changes in two stages along the depth direction. In the two-stage field plate structure, a peak of the electric field strength is generated at the bottom of the cell trench CT1 and at a boundary between the upper portion and the lower portion of the cell field plate electrode 32. Accordingly, the breakdown voltage of the vertical MOSFET is improved as compared with a case of the one-stage field plate structure.

However, in a case of the two-stage field plate structure, there is a problem that the breakdown voltage decreases at the end portion of the cell trench CT1 as compared with the one-stage field plate structure.

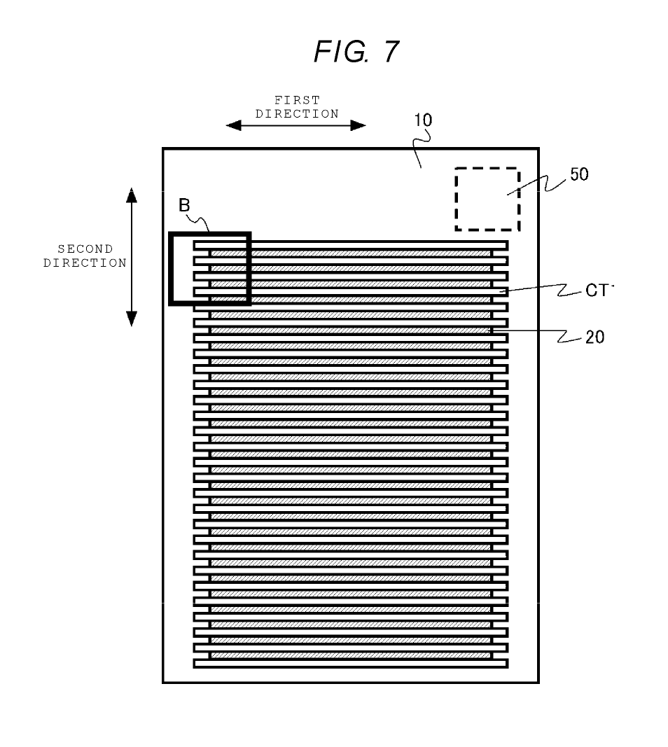

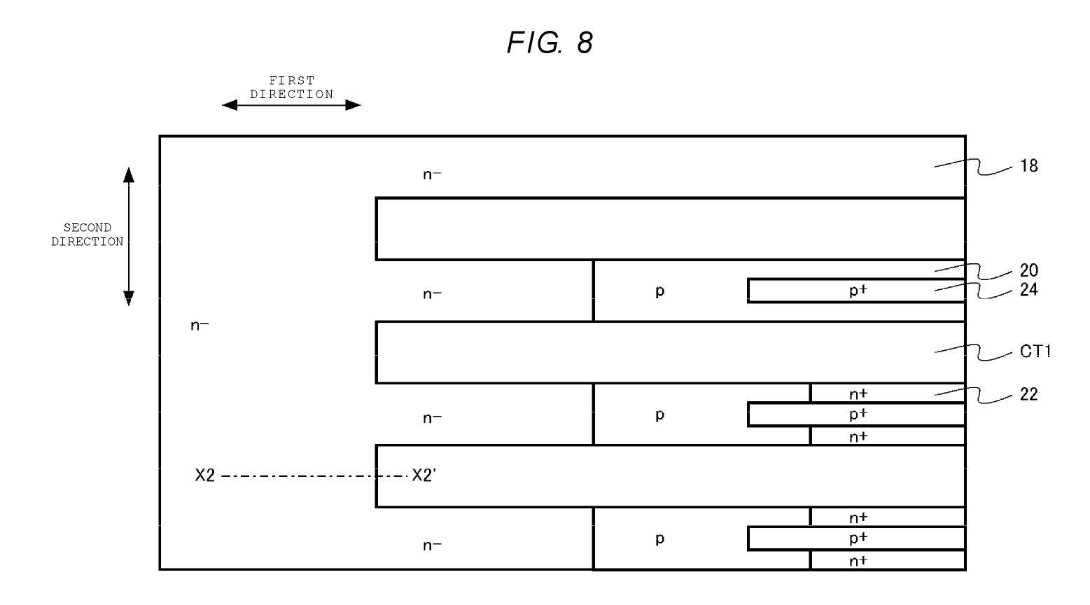

FIG. 7 is a schematic plan view of the semiconductor device according to the first and second comparative examples. FIG. 8 is a schematic plan view of a portion of the semiconductor device according to the first and second comparative examples. FIG. 8 is a schematic plan view of the portion surrounded by a frame line B of FIG. 7. FIG. 8 illustrates a layout of the cell trench CT1, the drain region 16, the drift region 18, the base region 20, the source region 22, and the base contact region 24, on the front surface of the semiconductor layer 10, of the portion surrounded by the frame line B of FIG. 7.

The semiconductor devices of the first and second comparative examples are different from the vertical MOSFET 100 of the first embodiment in that the semiconductor devices do not have a termination trench TT1.

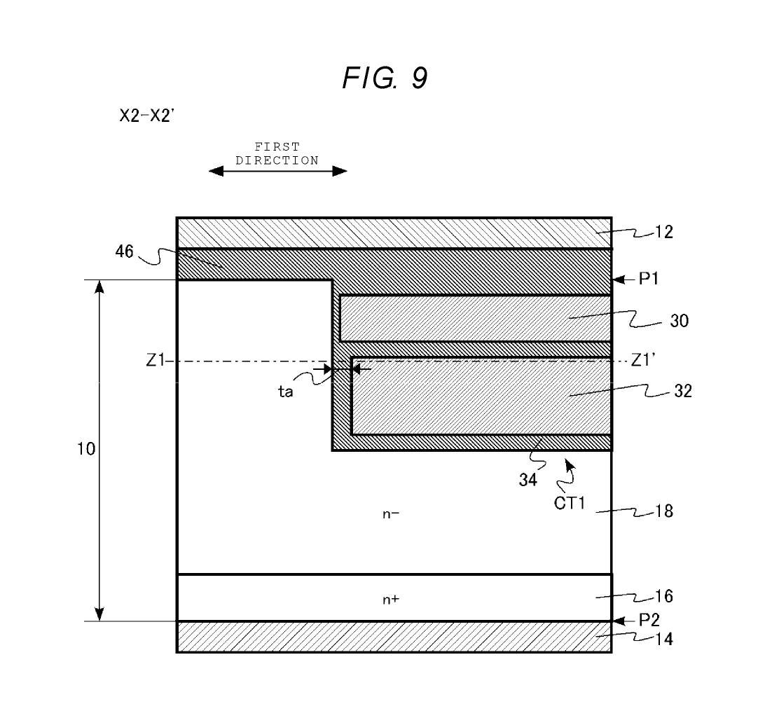

FIG. 9 is a schematic cross-sectional view of the portion of the semiconductor device of the first comparative example. FIG. 9 is a cross section taken along line X2-X2′of FIG. 8. As illustrated in FIG. 9, the film thickness (ta in FIG. 9) of the cell trench insulating layer 34 between the cell field plate electrode 32 and the semiconductor layer 10 at the end portion in the first direction of the cell trench CT1 is substantially constant.

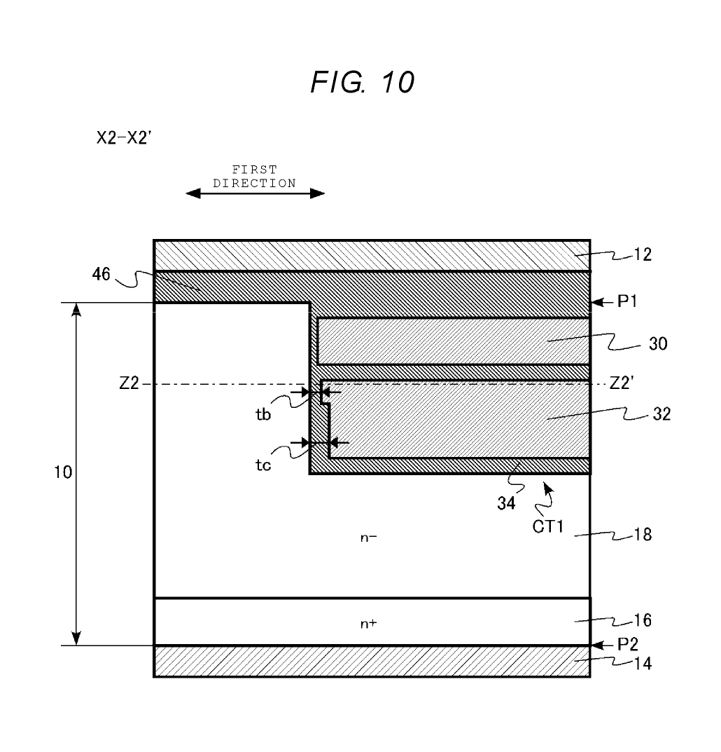

FIG. 10 is a schematic cross-sectional view of the portion of the semiconductor device of the second comparative example. FIG. 10 is a cross section taken along line X2-X2′ of FIG. 8. As illustrated in FIG. 10, there is a change in the film thickness of the cell trench insulating layer 34 between the cell field plate electrode 32 and the semiconductor layer 10 at the end portion of the cell trench CT1. The film thickness (tb in FIG. 10) of the upper portion of the cell trench insulating layer 34 is thinner than the film thickness (tc in FIG. 10) of the lower portion thereof.

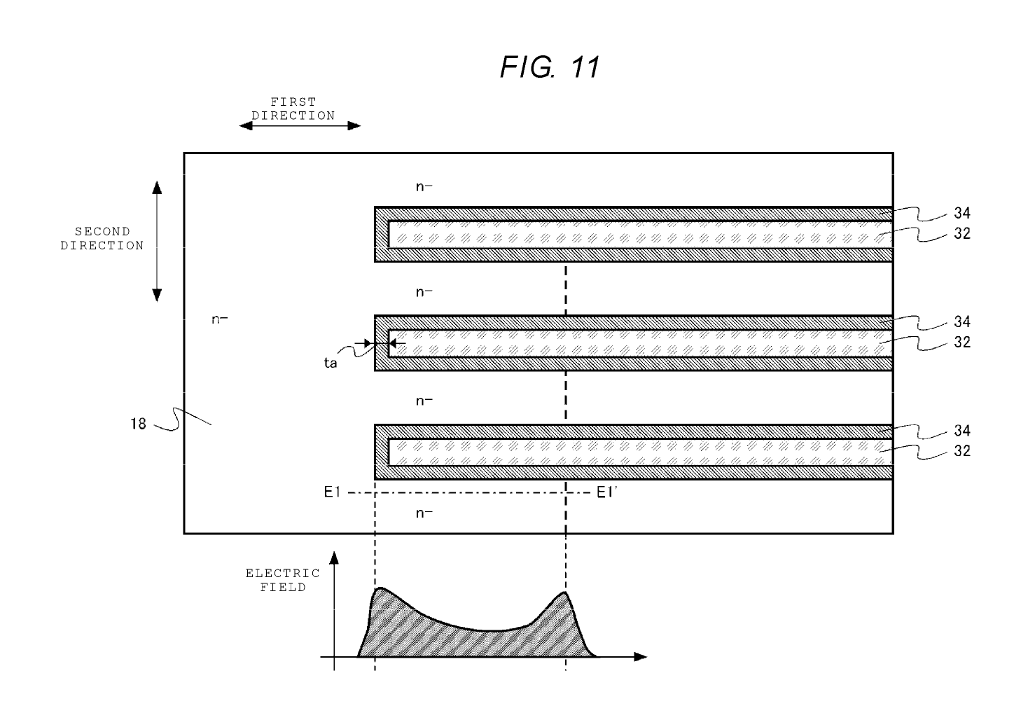

FIG. 11 is a schematic plan view and an electric field distribution diagram of the semiconductor device of the first comparative example. FIG. 11 is a cross-sectional view parallel to a first surface along line Z1-Z1′ of FIG. 9. The thick dotted line in FIG. 11 indicates a position of a boundary between the drift region 18 and the base region 20. Electric field distribution corresponds to the electric field distribution in a region along line E1-E1′ of FIG. 11.

As illustrated in FIG. 11, the electric field inside the drift region 18 increases at the end portion of the cell trench CT1. This is because charge balance of space charges in the semiconductor layer 10 is different and electric fields concentrate at the end portion of the cell trench CT1 as compared with the region between the two cell trenches CT1.

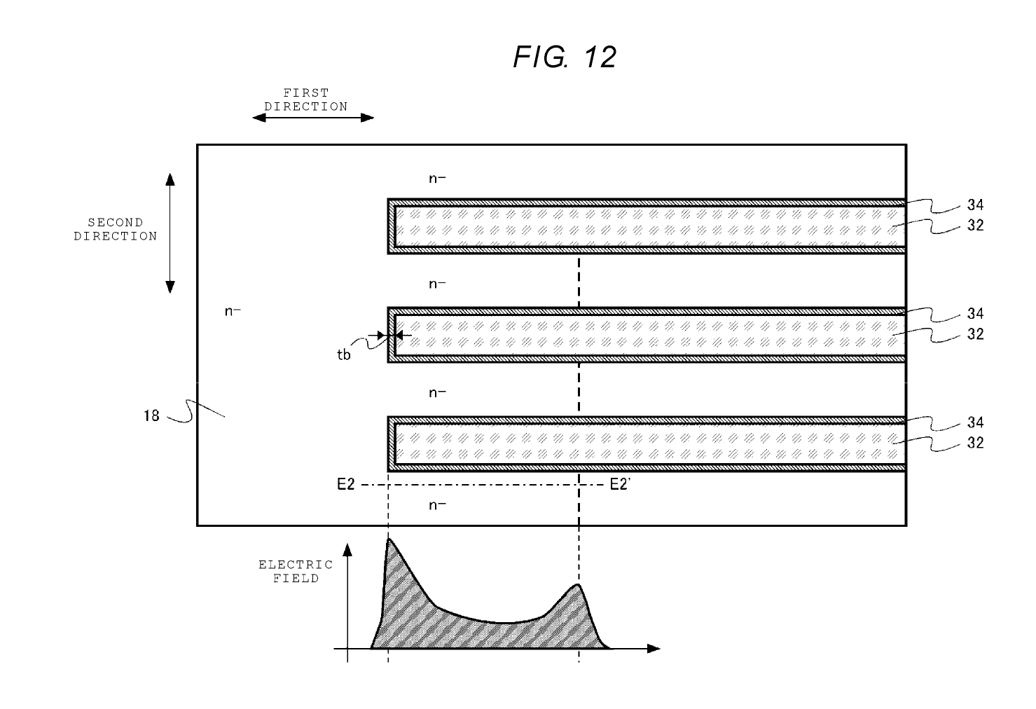

FIG. 12 is a schematic plan view and an electric field distribution diagram of the semiconductor device of the second comparative example. FIG. 12 is a cross-sectional view parallel to the first surface of line Z2-Z2′ of FIG. 10. The thick dotted line in FIG. 12 indicates the position of the boundary between the drift region 18 and the base region 20. Electric field distribution corresponds to the electric field distribution in a region along line E2-E2′ of FIG. 12.

As illustrated in FIG. 12, the electric field strength in the drift region 18 is higher than that in the first comparative example at the end portion of the cell trench CT1. This is caused by the fact that the film thickness (tb in FIG. 10) of the upper portion of the cell trench insulating layer 34 is thinner than the film thickness (ta in FIG. 11) of the cell trench insulating layer 34 of the first comparative example. Accordingly, avalanche breakdown easily occurs at the end portion of the cell trench CT1 and the breakdown voltage of the vertical MOSFET decreases as compared with the first comparative example.

In the vertical MOSFET of the first embodiment, the termination trench TT1 surrounding the plurality of cell trenches CT1 is provided. The end portion of the cell trench CT1 which faces the termination trench TT1. For that reason, as illustrated in FIG. 4, a mesa structure of the semiconductor layer 10 similar to the region between the two cell trenches CT1 is formed between the end portion of the cell trench CT1 and the termination trench TT1. For that reason, charge balance of space charges at the end portion of the cell trench CT1 is maintained similarly as in the region between the two cell trenches CT1. Accordingly, concentration of the electric fields at the end portion of the cell trench CT1 is prevented. Therefore, even in a case of having the two-stage field plate structure, a decrease in the breakdown voltage due to the end portion of the cell trench CT1 does not occur.

In the vertical MOSFET of the first embodiment, the first distance (e.g., d1 in FIG. 2) between the end portion of the cell trench CT1 and the termination trench TT1 is preferably smaller than the second distance (e.g., d2 in FIG. 2) between two adjacent cell trenches CT1. By satisfying the condition described above, charge balance of space charges at the end portion of the cell trench CT1 further approaches the charge balance of space charges in the region between the two cell trenches CT1 and concentration of the electric fields at the end portion of the cell trench CT1 is further prevented.

From the viewpoint of further preventing concentration of the electric fields at the end portion of the cell trench CT1, it is more preferable that the first distance d1 is 90% or less of the second distance d2.

The distance (e.g., d3 in FIG. 2) between the end portion of the cell trench CT1 and the end portion of the base region 20 is preferably greater than or equal to the distance (e.g., d4 in FIG. 3A) between the base region 20 and the end portion on the side of the rear surface of the semiconductor layer 10 of the cell trench CT1. By satisfying the condition described above, the distance between the end portion of the cell trench CT1 and the base region 20 in the first direction is equal to or greater than the distance between the base region 20 and the bottom of the cell trench CT1. For that reason, the electric field of the region, which is between the end portion of the cell trench CT1 and the base region 20 in the first direction, in the lateral direction is relaxed, and the breakdown voltage of the vertical MOSFET is improved.

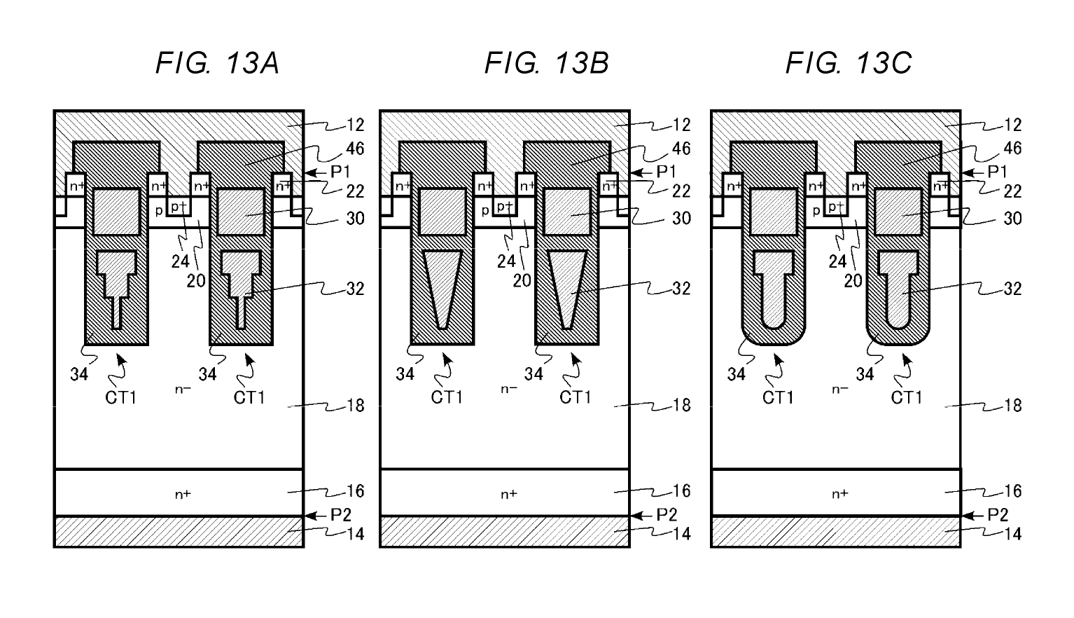

FIGS. 13A, 13B and 13C are schematic cross-sectional views of a portion of a semiconductor device of a modification example of the first embodiment. FIGS. 13A, 13B and 13C are cross-sectional views corresponding to FIG. 3A.

FIG. 13A is different from the first embodiment in that the structure illustrated in FIG. 13A is a structure in which the width of the cell field plate electrode 32 changes in three stages in the depth direction, in other words, the film thickness of the cell trench insulating layer 34 between the cell field plate electrode 32 and the semiconductor layer changes in three stages in the depth direction, that is, a three-stage field plate structure. A structure in which the semiconductor layer changes in four or more stages may also be adopted. FIG. 13B is different from the first embodiment in that the width of the cell field plate electrode 32 is continuously narrowed in the depth direction. In other words, the film thickness of the cell trench insulating layer 34 becomes continuously thinner in the direction from the front surface toward the rear surface of the semiconductor layer 10. Further, FIG. 13C is different from the first embodiment in that curvatures of the bottom of the cell trench CT1 and the bottom of the cell field plate electrode 32 are large.

Even in the modification examples of FIGS. 13A, 13B, and 13C, similarly to the first embodiment, the effect that the decrease in the breakdown voltage due to the end portion of the cell trench CT1 does not occur is obtained.

As described above, according to the vertical MOSFET of the first embodiment, the termination trench TT1 surrounding the plurality of cell trenches CT1 is provided so as to improve the breakdown voltage at the end portion of the cell trench CT1. Accordingly, it is possible to improve the breakdown voltage of the vertical transistor having the trench field plate structure.

### Second Embodiment

The semiconductor device of the second embodiment is different from the first embodiment in that a field plate electrode is located between the end portion of each of the plurality of first trenches in the first direction and the gate electrode. Hereinafter, descriptions of contents redundant with the first embodiment will be omitted.

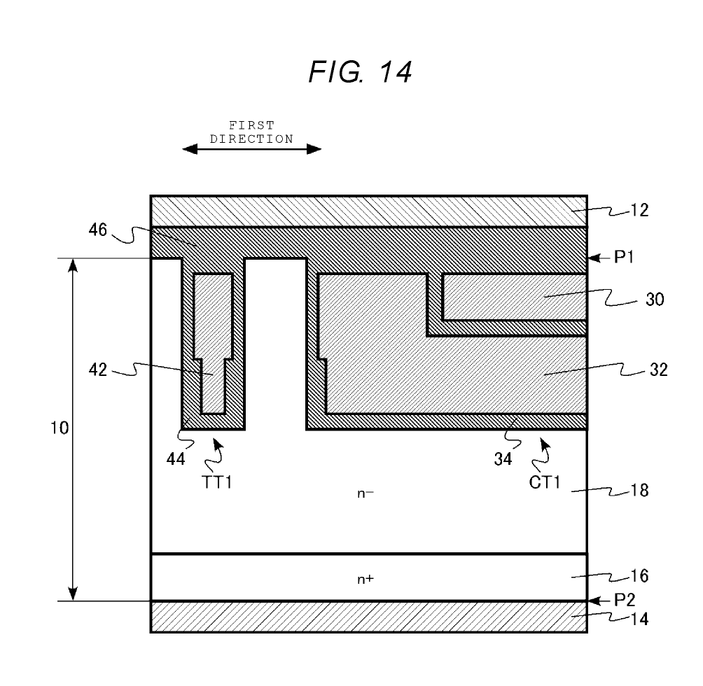

FIG. 14 is a schematic cross-sectional view of a portion of a semiconductor device of the second embodiment. FIG. 14 is a cross section corresponding to FIG. 4 of the first embodiment.

In the vertical MOSFET of the second embodiment, the cell field plate electrode 32 is present between the end portion of the cell trench CT1 and the cell gate electrode 30. Also, a termination gate electrode is not present in the termination trench TT1.

For example, when the cell field plate electrode 32 in the cell trench CT1 is formed by an etch-back process, the end portion of the cell trench CT1 and the top of the termination trench TT1 are covered with a mask material to thereby make it possible to form a structure of the second embodiment.

A region where the cell gate electrode 30 faces the semiconductor layer 10 via the cell trench insulating layer 34 is not present in the end portion of the cell trench CT1. Accordingly, a parasitic capacitance between a gate and a drain of the vertical MOSFET is reduced. Therefore, a switching speed of the vertical MOSFET is increased.

In a case where the termination gate electrode is present in the termination trench TT1, when the termination gate electrode is connected to a gate voltage, the parasitic capacitance between the gate and the drain increases, and the switching speed of the vertical MOSFET decreases. In the second embodiment, the termination gate electrode is not present in the termination trench TT1 and thus, reduction in the switching speed is prevented.

As described above, according to the vertical MOSFET of the second embodiment, it is possible to improve the breakdown voltage of the vertical transistor as in the first embodiment. Furthermore, it is possible to improve the switching speed of the vertical transistor.

### Third Embodiment

The semiconductor device of a third embodiment is different from the first embodiment in that a fourth semiconductor region having a first conductivity type is located between end portions of the second semiconductor region and the first semiconductor region in the first direction. The fourth semiconductor region is in contact with the first semiconductor region and has a first conductivity type impurity concentration that is lower than that of the first semiconductor region. Hereinafter, descriptions overlapping with the first embodiment will be omitted.

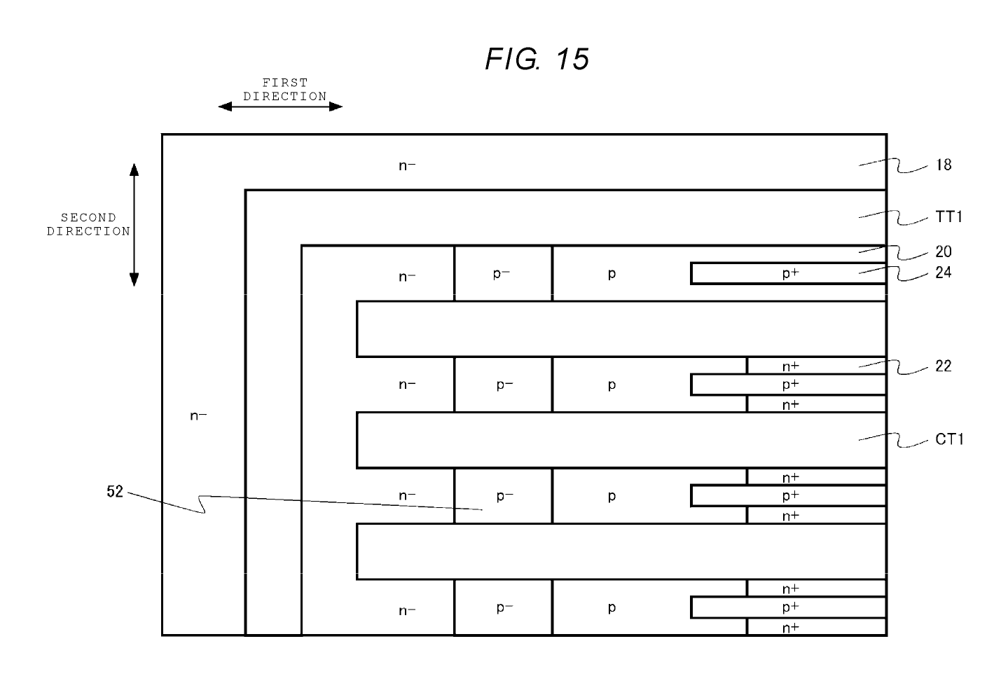

FIG. 15 is a schematic plan view of a portion of the semiconductor device of a third embodiment. FIG. 15 is a schematic plan view corresponding to FIG. 2 depicting the first embodiment.

A reserve region 52 is provided between the termination trench TT1 and the base region 20. The reserve region 52 is provided between the drift region 18 and the base region 20. The reserve region 52 is in contact with the drift region 18 and the base region 20.

The reserve region 52 is a p-type semiconductor region. The p-type impurity concentration of the reserve region 52 is lower than the p-type impurity concentration of the base region 20. The depth of the reserve region 52 can be made deeper or shallower than the base region 20.

The reserve region 52 is provided such that the electric field of the region between the end portion of the cell trench CT1 and the base region 20, in the lateral direction is relaxed, and the breakdown voltage of the vertical MOSFET is improved.

As described above, according to the vertical MOSFET of the third embodiment, the breakdown voltage of the vertical transistor is further improved.

### Fourth Embodiment

The semiconductor device of a fourth embodiment is different from the first embodiment in that a first semiconductor region is located between end portions of plurality of first trenches in the first direction and a second trench. Hereinafter, description overlapping with the first embodiment will be omitted.

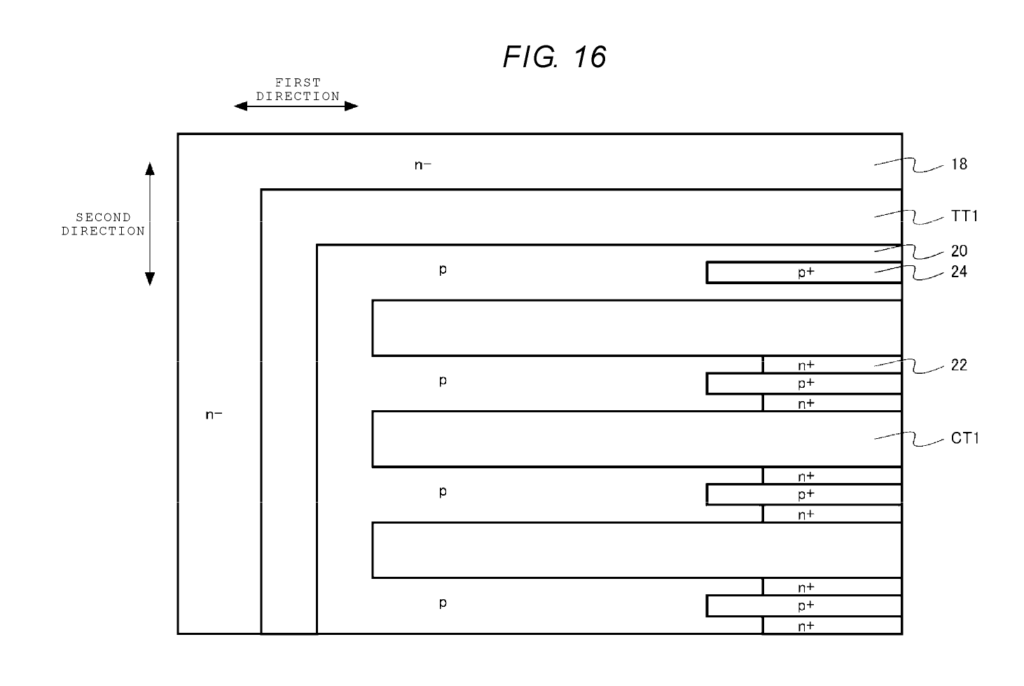

FIG. 16 is a schematic plan view of a portion of the semiconductor device of the fourth embodiment. FIG. 16 is a schematic plan view corresponding to FIG. 2 of the first embodiment.

The base region 20 is located between the end portions of the cell trenches CT1 in the first direction and the termination trench TT1. The base region 20 is located between the end portions of two cell trenches CT1. The base region 20 is provided on the entire surface of the semiconductor layer 10 between the end portion of the source region 22 in the first direction and the termination trench TT1.

By forming the entire surface of the semiconductor layer 10 between the end portion of the source region 22 in the first direction and the termination trench TT1 as the base region 20, the depletion layer extending in the lateral direction in the vicinity of the end portion of the cell trench CT1 hardly occurs. Accordingly, breakdown voltage design of the vertical MOSFET becomes easy.

As described above, according to the vertical MOSFET of the fourth embodiment, it is possible to improve the breakdown voltage of the vertical transistor as in the first embodiment. Furthermore, the breakdown voltage design of the vertical transistor becomes easy.

### Fifth Embodiment

The semiconductor device of a fifth embodiment is different from the first embodiment in that a plurality of third trenches provided in a semiconductor layer, extending in the first direction, and having a shorter length in the first direction than the plurality of first trenches, and a fourth trench provided in the semiconductor layer and surrounding the plurality of third trenches are further included. Hereinafter, descriptions of contents redundant with the first embodiment will be omitted.

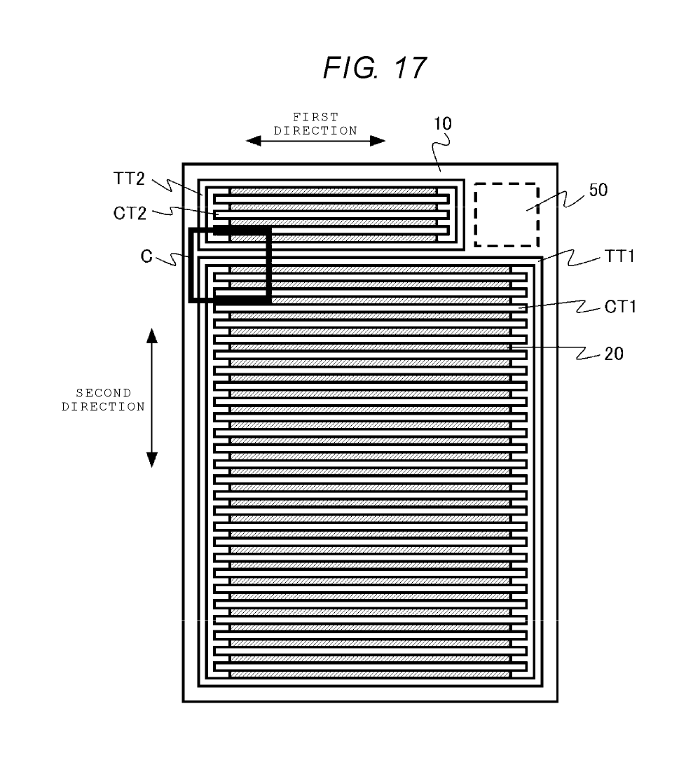

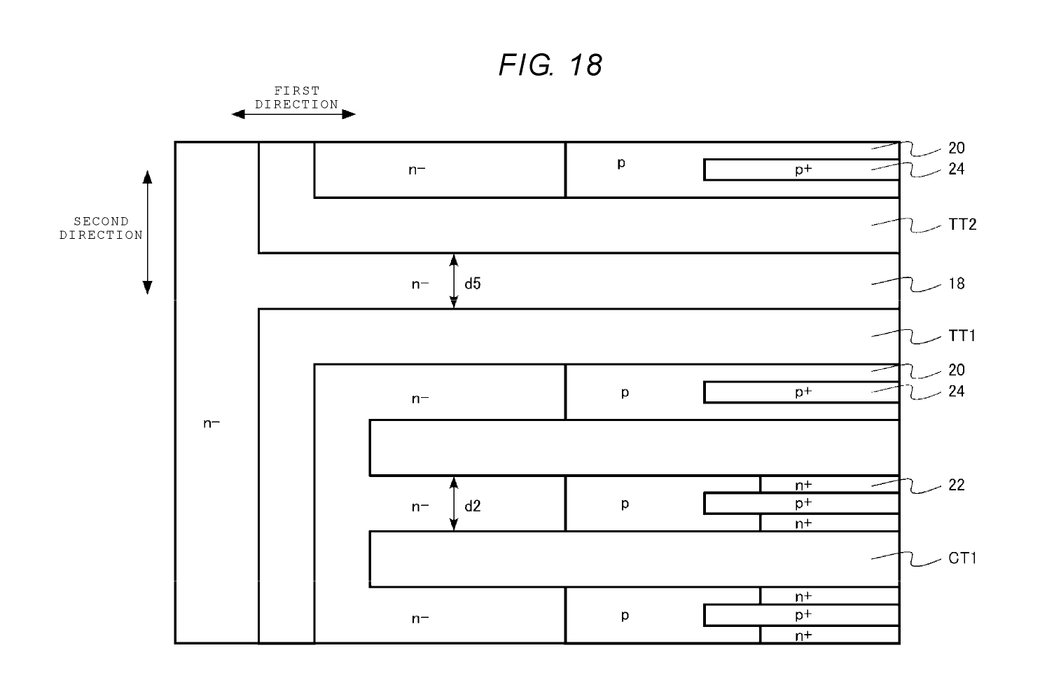

FIG. 17 is a schematic plan view of a semiconductor device according to the fifth embodiment. FIG. 17 is a schematic plan view corresponding that depicted in FIG. 1 for the first embodiment. FIG. 18 is a schematic plan view of a portion of the semiconductor device of the fifth embodiment. FIG. 18 is a schematic plan view of the portion surrounded by a frame line C in FIG. 17. FIG. 18 is a schematic plan view corresponding that depicted in FIG. 2 for the first embodiment.

The vertical MOSFET of the fifth embodiment includes the semiconductor layer 10, a first cell trench CT1, a first termination trench TT1, a second cell trench CT2, and a second termination trench TT2.

A plurality of first cell trenches CT1 extend in the first direction. The first direction is substantially parallel to the front surface (first surface) of the semiconductor layer 10. The first cell trenches CT1 are arranged at substantially regular intervals along the second direction.

The first termination trench TT1 surrounds the plurality of first cell trenches CT1. The first cell trenches CT1 are provided inside the first termination trench TT1. The first termination trench TT1 is spaced apart from each first cell trench CT1 at a predetermined distance.

The plurality of second cell trenches CT2 extend in the first direction. The first direction is substantially parallel to the front surface (first surface) of the semiconductor layer 10. The second cell trenches CT2 are arranged at substantially regular intervals along the second direction. The length of each second cell trench CT2 in the first direction is shorter than the length of each first cell trench CT1 in the first direction.

The second termination trench TT2 surrounds the plurality of second cell trenches CT2. The second cell trenches CT2 are provided inside the second termination trench TT2. The second termination trench TT2 is provided spaced apart from each second cell trench CT2 at a predetermined distance.

According to the fifth embodiment, the second cell trenches CT2 are provided in addition to the first cell trenches CT1 so that integration of the vertical MOSFET is improved. Accordingly, the on-current of the vertical MOSFET is increased.

The distance (e.g., d2 in FIG. 18) between two adjacent first cell trenches CT1 and the distance (e.g., d5 in FIG. 18) between the first termination trench TT1 and the second termination trench TT2 are preferably approximately the same. By satisfying this condition, processing accuracy of the trenches is improved. A surplus, unused region on the front surface area of the semiconductor layer 10 is reduced and the size of the vertical MOSFET device can be reduced.

As described above, according to the vertical MOSFET of the fifth embodiment, it is possible to improve the breakdown voltage of a vertical transistor similarly as in the first embodiment. Furthermore, the degree of integration in the vertical transistor is improved and the on-current is increased.

### Sixth Embodiment

The semiconductor device of a sixth embodiment is different from the first embodiment in that a plurality of third trenches provided in a semiconductor layer and a fourth trench is provided in the semiconductor layer. The third trenches extend in a first direction and have a shorter length along the first direction than the first trenches. The fourth trench extends in the first direction and is located between the plurality of first trenches and the plurality of third trenches. A second trench surrounds the plurality of first trenches, the plurality of third trenches, and the fourth trench, and the minimum distance between an end portion of the fourth trench and the second trench is less than the minimum distance between end portions of the first trenches and the second trench and also is less than the minimum distance between end portions of third trenches and the second trench. Hereinafter, descriptions overlapping with the first embodiment will be omitted.

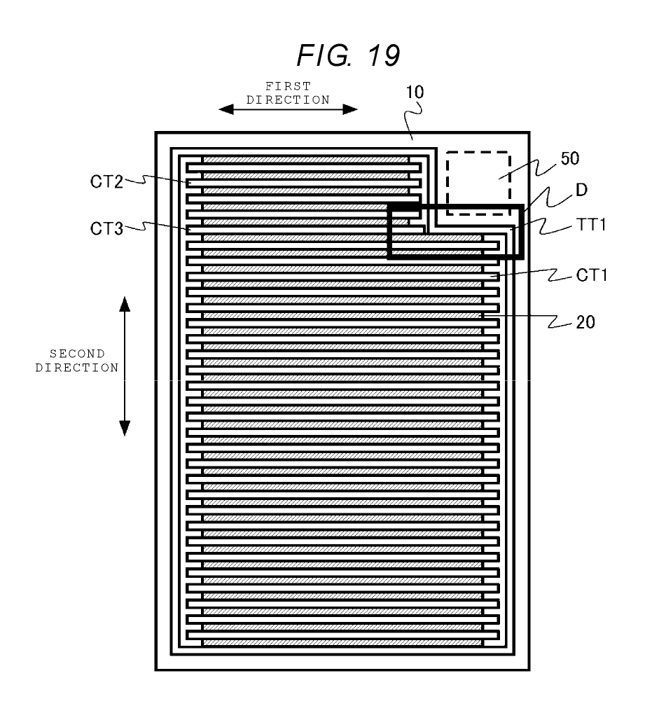

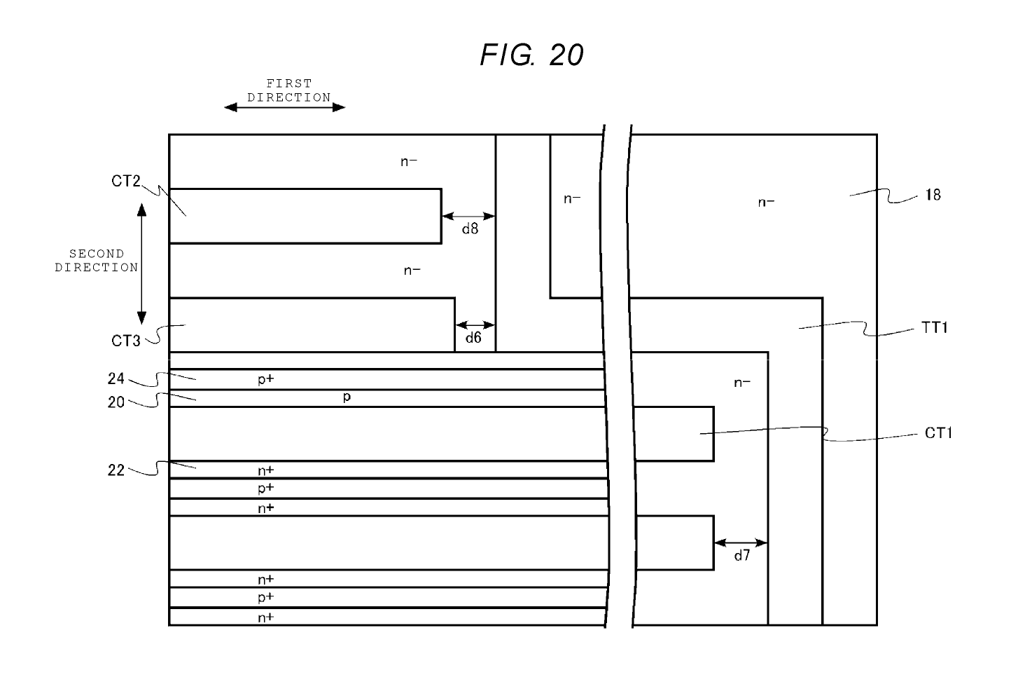

FIG. 19 is a schematic plan view of a semiconductor device of the sixth embodiment. FIG. 19 is a schematic plan view corresponding that depicted in FIG. 1 for the first embodiment. FIG. 20 is a schematic plan view of a portion of a semiconductor device of the sixth embodiment. FIG. 20 is a schematic plan view of a portion surrounded by a frame line D in FIG. 19. FIG. 20 is a schematic plan view corresponding that depicted in FIG. 2 for the first embodiment.

The vertical MOSFET of the sixth embodiment includes the semiconductor layer 10, the first cell trenches CT1), the termination trench TT1, the second cell trenches CT2, a third cell trench CT3.

The plurality of first cell trenches CT1 extend in the first direction. The first direction is substantially parallel to the front surface (first surface) of the semiconductor layer 10. The first cell trenches CT1 are arranged at substantially regular intervals along the second direction.

The plurality of second cell trenches CT2 extend in the first direction. The first direction is substantially parallel to the front surface (first surface) of the semiconductor layer 10. The second cell trenches CT2 are arranged at substantially regular intervals along the second direction. The length of the second cell trenches CT2 in the first direction is shorter than the length of the first cell trenches CT1 in the first direction.

The third cell trench CT3 extends in the first direction. The first direction is substantially parallel to the front surface (first surface) of the semiconductor layer 10. The third cell trench CT3 is located between first cell trenches CT1 and second cell trenches CT2. The length of the third cell trench CT3 in the first direction is shorter than the length of the first cell trenches CT1 in the first direction. The length of the third cell trench CT3 in the first direction is longer than the length of the second cell trenches CT2 in the first direction.

The termination trench TT1 surrounds the plurality of first cell trenches CT1, the plurality of second cell trenches CT2, and the third cell trench CT3.

According to the sixth embodiment, the second cell trench CT2 is provided in addition to the first cell trench CT1 so that the degree of integration of the vertical MOSFET is improved. Accordingly, the on-current of the vertical MOSFET is increased.

A distance (e.g., d6 in FIG. 20) between the end portion of the third cell trench CT3 and the termination trench TT1 is smaller than a distance (e.g., d7 in FIG. 20) between the end portion of a first cell trench CT1 and the termination trench TT1 and also smaller than a distance (e.g., d8 in FIG. 20) between the end portion of a second cell trench CT2 and the termination trench TT1. The distance (e.g., d7 in FIG. 20) between the end portion the first cell trench CT1 and the termination trench TT1 and the distance (e.g., d8 in FIG. 20) between the end portion of the second cell trench CT2 and the termination trench TT1 are, for example, approximately the same.

The end portion of the third cell trench CT3 is present at a point where the termination trench TT1 is bent. The distance (e.g., d6 in FIG. 20) between the end portion of the third cell trench CT3 and the termination trench TT1 is made shorter such that charge balance with space charges is adjusted and a concentration of electric fields at the end portion of the third cell trench CT3 is reduced. Accordingly, the reduction in the breakdown voltage of the vertical MOSFET is prevented.

As described above, according to the vertical MOSFET of the sixth embodiment, it is possible to improve the breakdown voltage of a vertical transistor similarly as to that in the first embodiment. Furthermore, the degree of integration of the vertical transistor can be improved and the on-current is increased.

### Seventh Embodiment

A semiconductor device according to a seventh embodiment is different from the first embodiment in that the length of the first semiconductor region between two adjacent first trenches in a sub-portion of the plurality of first trenches is shorter than the length of the first semiconductor region between two adjacent first trenches in the remaining portion of the plurality of first trenches. Hereinafter, descriptions of contents overlapping with the first embodiment will be omitted.

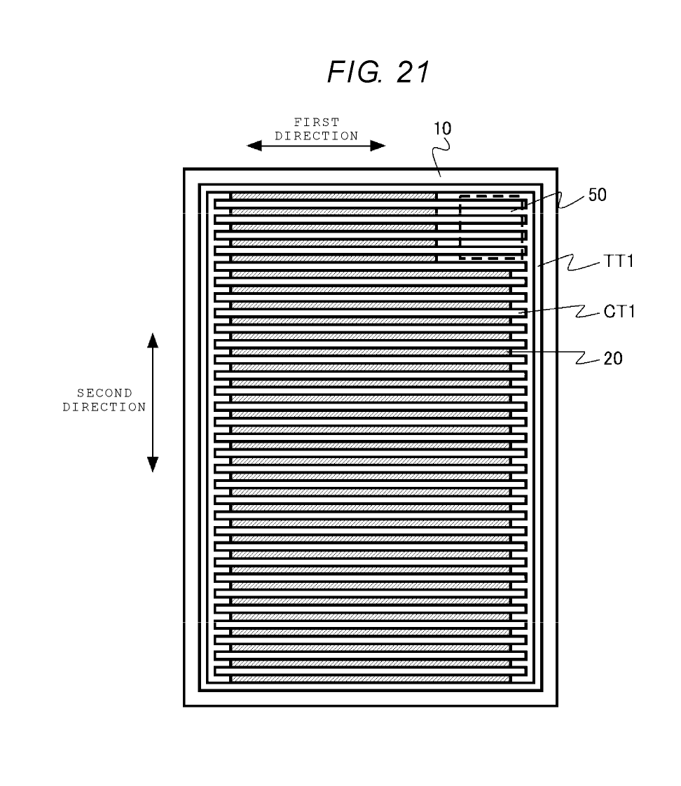

FIG. 21 is a schematic plan view of a semiconductor device of the seventh embodiment. FIG. 21 is a schematic plan view corresponding that depicted in FIG. 1 for the first embodiment.

A portion of the plurality of first cell trenches CT1 is provided under the gate pad electrode 50. The length of the base region 20, between two adjacent first cell trenches CT1 in this portion of the plurality of first cell trenches CT1 provided under the gate pad electrode 50 is shorter, in the first direction, than the length of the base region 20 between two adjacent first cell trenches CT1 of another portion of the plurality of first cell trenches CT1. The base region 20 is not provided in the region under the gate pad electrode 50.

According to the seventh embodiment, as the number of the first cell trenches CT1 increases, the degree of integration of the vertical MOSFET improves. Accordingly, the on-current of the vertical MOSFET increases.

The base region 20 can be removed from the region under the gate pad electrode 50 since it is anyways difficult to provide a contact to the base region 20 so as to make it possible to prevent hole extraction efficiency from being lowered in this region. Accordingly, a reduction in avalanche resistance of the vertical MOSFET is prevented.

As described above, according to the vertical MOSFET of the seventh embodiment, it is possible to improve the breakdown voltage of the vertical transistor similarly as in the first embodiment. Furthermore, the degree of integration of the vertical transistor is improved and the on-current is increased.

### Eighth Embodiment

A semiconductor device of an eighth embodiment includes a semiconductor layer having a first surface and a second surface which faces the first surface; a first electrode in contact with the first surface; a second electrode in contact with the second surface; a plurality of trenches provided in the semiconductor layer and extending in a first direction substantially parallel to the first surface; a gate electrode provided in each of the plurality of trenches; a field plate electrode provided in each of the plurality of trenches and provided between the gate electrode and the second surface; an insulating layer including a first portion provided in each of the plurality of trenches, located between the gate electrode and the semiconductor layer, and has a first film thickness, a second portion located between the field plate electrode and the semiconductor layer and having a second film thickness thicker than the first film thickness, a third portion located between the second portion, which is located between the field plate electrode and the semiconductor layer, and the second surface and having a third film thickness thicker than the second film thickness, and a fourth portion located at a portion, which is between the end portion of the field plate electrode in the first direction and the semiconductor layer and which is at substantially the same depth from the first surface, and having a fourth film thickness thicker than the second film thickness; a first semiconductor region having a first conductivity type provided in the semiconductor layer and located between two adjacent trenches of the plurality of trenches; a second semiconductor region having a second conductivity type provided in the semiconductor layer and located between the first semiconductor region and the second surface; and a third semiconductor region having the second conductivity type provided in the semiconductor layer, located between the first semiconductor region and the first electrode, and electrically connected to the first electrode.

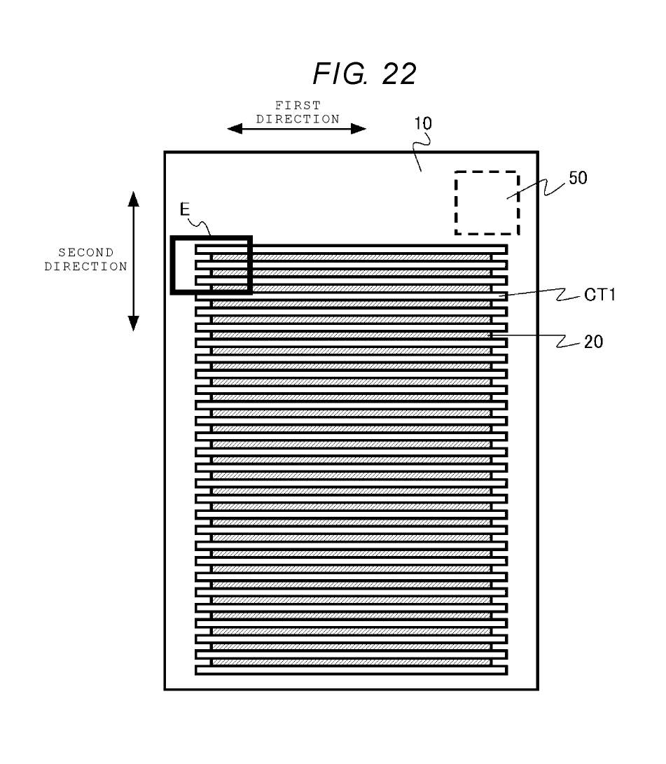

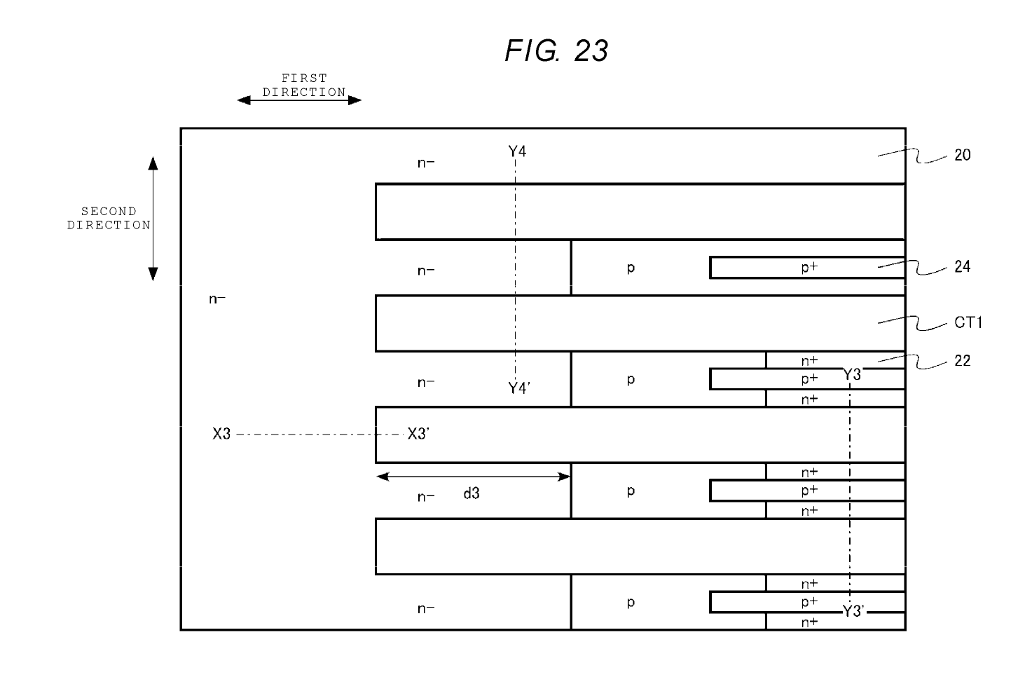

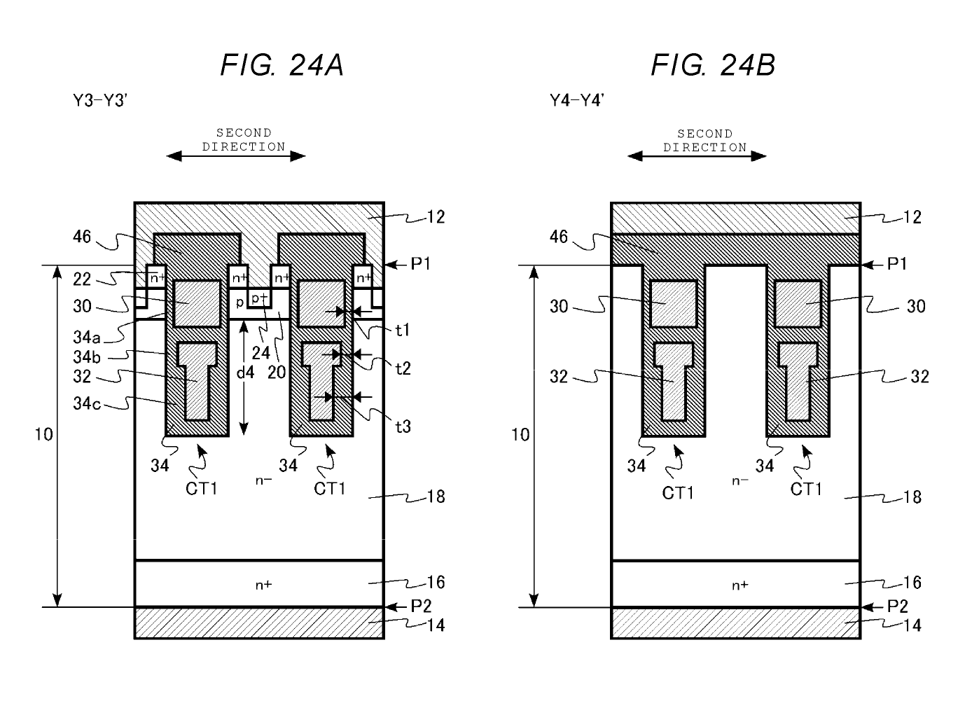

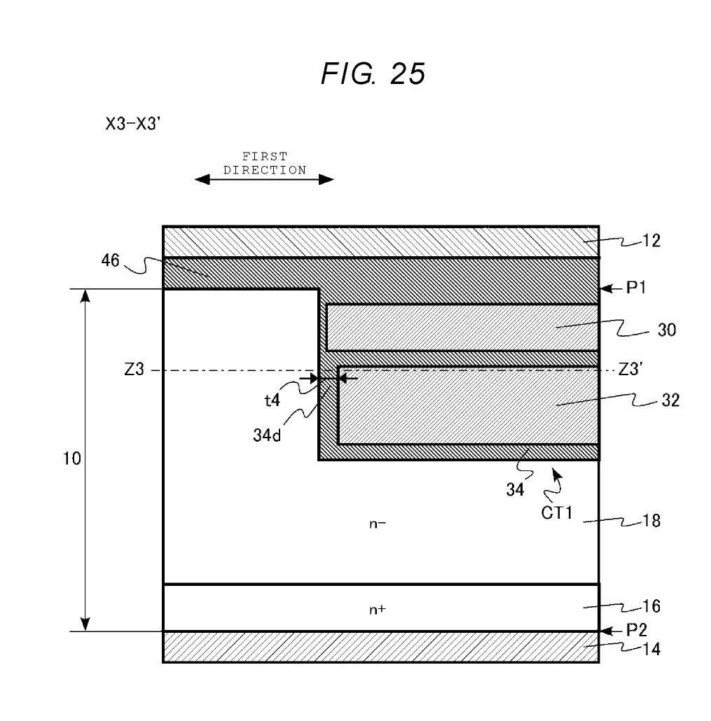

FIG. 22 is a schematic plan view of the semiconductor device of the eighth embodiment. FIG. 23 is a schematic plan view of a portion of the semiconductor device of the eighth embodiment. FIG. 23 is a schematic plan view of a portion surrounded by a frame line E in FIG. 22. FIGS. 24A and 24B are schematic cross-sectional views of the portion of the semiconductor device of the eighth embodiment. FIG. 24A is a cross section taken along line Y3-Y3′ of FIG. 23, and FIG. 24B is a cross section taken along line Y4-Y4′ of FIG. 23. FIG. 25 is another schematic cross-sectional view of the portion of the semiconductor device of the eighth embodiment. FIG. 25 is a cross section taken along line X3-X3′ of FIG. 23.

The semiconductor device of the eighth embodiment is a vertical MOSFET having a vertical trench gate structure in which a gate electrode is provided in a trench formed in a semiconductor layer. The vertical MOSFET of the eighth embodiment also has a trench field plate structure. The vertical MOSFET of the eighth embodiment is an n-channel type transistor using electrons as carriers.

The vertical MOSFET of the eighth embodiment includes the semiconductor layer 10, the cell trenches CT1, the source electrode 12, the drain electrode 14, the drain region 16, the drift region 18, the base region 20, the source region 22, the base contact region 24, the cell gate electrode 30, the cell field plate electrode 32), the cell trench insulating layer 34, and the interlayer insulating layer 46. The cell trench insulating layer 34 includes the gate insulating film 34a, the upper field plate insulating film 34b, the lower field plate insulating film 34c, an end portion field plate insulating film 34d . Further, the vertical MOSFET of this eighth embodiment has the gate pad electrode 50.

FIG. 23 schematically illustrates a layout of the plurality of cell trenches CT1, the base region 20, and the gate pad electrode 50. The cell trenches CT1 are provided in the semiconductor layer 10.

The semiconductor layer 10 has a first surface P1 (hereinafter, also referred to as a front surface) and a second surface P2 (hereinafter, also referred to as a rear surface) which faces the first surface P1. The semiconductor layer 10 is, for example, single crystal silicon. A film thickness of the semiconductor layer 10 is, for example, between 50 μm and 300 μm.

The plurality of cell trenches CT1 extend in the first direction. The first direction is substantially parallel to the front surface of the semiconductor layer 10. The plurality of cell trenches CT1 are arranged at substantially regular intervals in a second direction orthogonal to the first direction.

The gate pad electrode 50 is provided outside the region of the plurality of cell trenches CT1.

At least a portion of the source electrode 12 is in contact with a first surface P1 of the semiconductor layer 10. The source electrode 12 is, for example, metal. A source voltage is applied to the source electrode 12. The source voltage is, for example, 0 V.

At least a portion of the drain electrode 14 is in contact with a second surface P2 of the semiconductor layer 10. The drain electrode 14 is, for example, metal. A drain voltage is applied to the drain electrode 14. The drain voltage is, for example, between 200 V and 1500 V.

The cell gate electrode 30 is provided in each of the plurality of cell trenches CT1. The cell gate electrode 30 is, for example, polycrystalline silicon containing n-type impurities or p-type impurities.

A gate voltage is applied to the cell gate electrode 30. By changing the gate voltage, an ON/OFF switching operation of the vertical MOSFET 100 is realized.

The cell field plate electrode 32 is provided in each of the plurality of cell trenches CT1. The cell field plate electrode 32 is provided between the cell gate electrode 30 and the rear surface of the semiconductor layer 10. The cell field plate electrode 32 is, for example, polycrystalline silicon containing n-type impurities or p-type impurities.

A width of an upper portion of the cell field plate electrode 32 is wider than the width of a lower portion of the cell field plate electrode 32 . The vertical MOSFET of the first embodiment has a so-called two-stage field plate structure in which the width of the cell field plate electrode 32 changes in stages along the depth direction.

For example, a source voltage is applied to the cell field plate electrode 32. A configuration in which a gate voltage is applied to the cell field plate electrode 32 is also possible.

The cell gate electrode 30 and the cell field plate electrode 32 are surrounded by the cell trench insulating layer 34. The cell trench insulating layer 34 has the gate insulating film 34a, the upper field plate insulating film 34b, the lower field plate insulating film 34c, and the end portion field plate insulating film 34d . The cell trench insulating layer 34 is, for example, silicon oxide. It does not particularly matter whether the gate insulating film 34a, the upper field plate insulating film 34b, the lower field plate insulating film 34c, and the end portion field plate insulating film 34d are formed in the same process, and portions thereof may be formed in separate process steps.

The gate insulating film 34a is located between the cell gate electrode 30 and the semiconductor layer 10. The gate insulating film 34a has a first film thickness t1.

The upper field plate insulating film 34b is located between the upper portion of the cell field plate electrode 32 and the semiconductor layer 10. The upper field plate insulating film 34b has a second film thickness t2.

The lower field plate insulating film 34c is located between a lower portion of the cell field plate electrode 32 and the semiconductor layer 10. The lower field plate insulating film 34c is located between the upper field plate insulating film 34b and a rear surface of the semiconductor layer 10. The lower field plate insulating film 34c has the third film thickness t3.

The second film thickness t2 of the upper field plate insulating film 34b is thicker than the first film thickness t1 of the gate insulating film 34a. The third film thickness t3 of the lower field plate insulating film 34c is thicker than the second film thickness t2 of the upper field plate insulating film 34b.

The second film thickness t2 of the upper field plate insulating film 34b is, for example, between 40% and 60% of the third film thickness t3.

The end portion field plate insulating film 34d is located between the end portion of the cell field plate electrode 32 and the semiconductor layer 10. The end portion field plate insulating film 34d is located at substantially the same depth from the upper field plate insulating film 34b and the front surface (first surface) of the semiconductor layer 10. The depth of the end portion field plate insulating film 34d from the front surface (first surface) of the semiconductor layer 10 is substantially the same as the depth from the front surface (first surface) of the semiconductor layer 10 of the upper field plate insulating film 34b. Here, the “depth” is a distance in a direction from the surface (first surface) of the semiconductor layer 10 toward the rear surface (second surface).

The fourth film thickness t4 of the end portion field plate insulating film 34d is thicker than the second film thickness t2 of the upper field plate insulating film 34b. The fourth film thickness t4 is, for example, substantially the same as the third film thickness t3 of the lower field plate insulating film 34c.

For example, after an insulating film is formed on the inner surface of the cell trench CT1, a portion corresponding to the lower field plate insulating film 34c is covered with a first mask material and the insulating film is then etched so as to make it possible to form the upper field plate insulating film 34b. When the insulating film is etched, the end portion of the cell trench CT1 is covered with a second mask material so as to make it possible to form the end portion field plate insulating film 34d without etching the insulating film. For example, it is possible to use polycrystalline silicon as the first mask material and photoresist as the second mask material.

The base region 20 is provided in the semiconductor layer 10. The base region 20 is located between two adjacent cell trenches CT1. The base region 20 is a p-type semiconductor region. A region of the base region 20 in contact with the gate insulating film 34a functions as a channel region of the vertical MOSFET 100. The base region 20 is electrically connected to the source electrode 12.

The source region 22 is provided in the semiconductor layer 10. The source region 22 is provided between the base region 20 and the front surface of the semiconductor layer 10. The source region 22 is provided between the base region 20 and the source electrode 12. The source region 22 is an n-type semiconductor region. The source region 22 is electrically connected to the source electrode 12.

The base contact region 24 is provided in the semiconductor layer 10. The base contact region 24 is provided between the base region 20 and the source electrode 12. The base contact region 24 is a p-type semiconductor region. P-type impurity concentration of the base contact region 24 is higher than the p-type impurity concentration of the base region 20. The base contact region 24 is electrically connected to the source electrode 12.

The drift region 18 is provided in the semiconductor layer 10. The drift region 18 is provided between the base region 20 and the rear surface of the semiconductor layer 10. The drift region 18 is an n-type semiconductor region. N-type impurity concentration of the drift region 18 is lower than n-type impurity concentration of the source region 22.

The drain region 16 is provided in the semiconductor layer 10. The drain region 16 is provided between the drift region 18 and the rear surface of the semiconductor layer 10. The drain region 16 is an n-type semiconductor region. The n-type impurity concentration of the drain region 16 is higher than the n-type impurity concentration of the drift region 18. The drain region 16 is electrically connected to the drain electrode 14.

The gate pad electrode 50 is provided on the semiconductor layer 10. The gate pad electrode 50 is provided on the side of the front surface of the semiconductor layer 10. The gate pad electrode 50 is electrically connected to at least the cell gate electrode 30. The gate pad electrode 50 is, for example, metal.

FIG. 23 illustrates a layout of the cell trenches CT1, the drain region 16, the drift region 18, the base region 20, the source region 22, and the base contact region 24, on the front surface of the semiconductor layer 10, of a portion surrounded by the frame line E of FIG. 22.

For example, the distance (e.g., d3 in FIG. 23) between the end portion of the cell trench CT1 and the end portion of the base region 20 greater than or equal to a distance (e.g., d4 in FIG. 24A) between the base region 20 and the end portion on the side of the rear surface of the semiconductor layer 10 of the cell trench CT1.

First, effect of the two-stage field plate structure will be described. FIG. 5 and FIG. 6 are explanatory diagrams of the effect of the field plate structure.

FIG. 5 is a schematic sectional view and an electric field distribution diagram of the semiconductor device of the first comparative example. The semiconductor device of the first comparative example is the vertical MOSFET. FIG. 5 illustrates a cross section of the cell trench CT1 of the first comparative example. The cross section of FIG. 5 is the cross section corresponding to the cross section of FIG. 3A. The vertical MOSFET of the first comparative example has a one-stage field plate structure.

FIG. 6 is a schematic cross-sectional view and an electric field distribution diagram of a semiconductor device of a second comparative example. The semiconductor device of the second comparative example is the vertical MOSFET. FIG. 6 illustrates the cross section of the cell trench CT1 of the second comparative example. The cross section of FIG. 6 corresponds to the cross section of FIG. 3A. The vertical MOSFET of the second comparative example has the two-stage field plate structure.

In the two-stage field plate structure illustrated in FIG. 5, a width of the upper portion of the cell field plate electrode 32 is substantially constant, and there is no step in the cell field plate electrode 32. The breakdown voltage of the vertical MOSFET is improved by increasing an integrated value of the electric field in the depth direction. In the one-stage field plate structure, a peak of an electric field strength is generated at the bottom of the cell trench CT1 so that the breakdown voltage of the vertical MOSFET is improved.

In the two-stage field plate structure illustrated in FIG. 6, the width of the upper portion of the cell field plate electrode 32 is wider than the width of the lower portion. In the two-stage field plate structure in which the width of the cell field plate electrode 32 changes stepwise, a peak of the electric field is generated at the bottom portion of the cell trench CT 1 and the boundary between the upper portion and the lower portion of the cell field plate electrode 32, so that the breakdown voltage of the vertical MOSFET is improved as compared with the case of the one-stage field plate structure.

However, in the case of a two-stage field plate structure, there is a problem in that the breakdown voltage decreases at the end portion of the cell trench CT1, as compared with the one-stage field plate structure.

FIG. 7 is a schematic plan view of the semiconductor device according to the first and second comparative examples. FIG. 8 is a schematic plan view of a portion of the semiconductor device according to the first and second comparative examples. FIG. 8 is a schematic plan view of the portion surrounded by a frame line B of FIG. 7. FIG. 8 illustrates a layout of the cell trench CT1, the drain region 16, the drift region 18, the base region 20, the source region 22, and the base contact region 24 on the front surface of the semiconductor layer 10, of the portion surrounded by the frame line B of FIG. 7.

The semiconductor devices of the first and second comparative examples are different from the vertical MOSFET 100 of the first embodiment in that the comparative semiconductor devices do not have a termination trench TT1.

FIG. 9 is a schematic cross-sectional view of the portion of the semiconductor device of the first comparative example. FIG. 9 is a cross section taken along line X2-X2′of FIG. 8. As illustrated in FIG. 9, the film thickness (ta in FIG. 9) of the cell trench insulating layer 34 between the cell field plate electrode 32 and the semiconductor layer 10 at the end portion in the first direction of the cell trench CT1 is substantially constant.

FIG. 10 is a schematic cross-sectional view of the portion of the semiconductor device of the second comparative example. FIG. 10 is a cross section taken along line X2-X2′ of FIG. 8. As illustrated in FIG. 10, there is a change in the film thickness of the cell trench insulating layer 34 between the cell field plate electrode 32 and the semiconductor layer 10 at the end portion of the cell trench CT1. The film thickness (tb in FIG. 10) of the upper portion of the cell trench insulating layer 34 is thinner than the film thickness (tc in FIG. 10) of the lower portion thereof.

FIG. 11 is a schematic plan view and an electric field distribution diagram of the semiconductor device of the first comparative example. FIG. 11 is a cross-sectional view parallel to a first surface along line Z1-Z1′ of FIG. 9. The thick dotted line in FIG. 11 indicates a position of a boundary between the drift region 18 and the base region 20. The electric field distribution corresponds to the electric field distribution in a region along line E1-E1′ of FIG. 11.

As illustrated in FIG. 11, the electric field in the drift region 18 increases at the end portion of the cell trench CT1. This is because charge balance of space charges in the semiconductor layer 10 is different and the electric field concentrates at the end portion of the cell trench CT1 as compared to the region between the two adjacent cell trenches CT1.

FIG. 12 is a schematic plan view and an electric field distribution diagram of the semiconductor device of the second comparative example. FIG. 12 is a cross-sectional view parallel to the first surface of line Z2-Z2′ of FIG. 10. The thick dotted line in FIG. 12 indicates the position of the boundary between the drift region 18 and the base region 20. The electric field distribution is the electric field distribution in the region along line E2-E2′ of FIG. 12.

As illustrated in FIG. 12, the electric field in the drift region 18 is higher than the first comparative example at the end portion of the cell trench CT1. This is caused by the fact that the film thickness (tb in FIG. 10) of the upper portion of the cell trench insulating layer 34 is thinner than the film thickness (ta in FIG. 11) of the cell trench insulating layer of the first comparative example. Accordingly, the avalanche breakdown more easily occurs at the end portion of the cell trench CT1 as compared with the first comparative example and the breakdown voltage of the vertical MOSFET decreases.

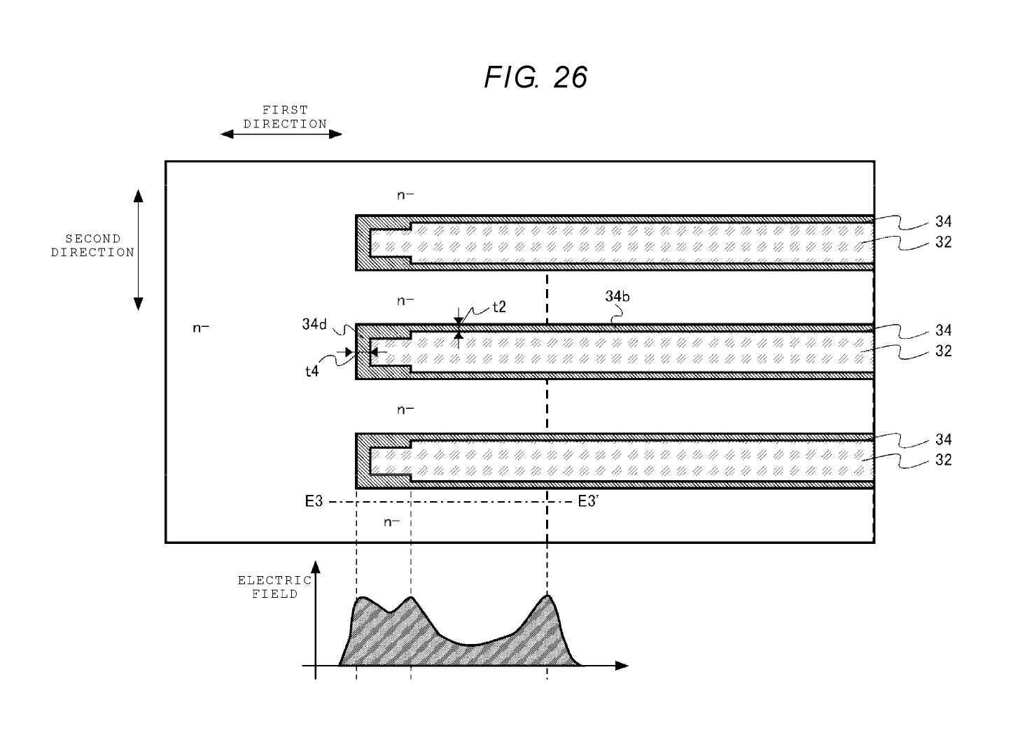

FIG. 26 is a schematic plan view and an electric field distribution diagram of a semiconductor device of the eighth embodiment. FIG. 26 is a cross-sectional view parallel to the front surface (first surface) of the semiconductor layer 10 taken along line Z3-Z3′ of FIG. 25. The thick dotted line in FIG. 26 indicates the position of the boundary between the drift region 18 and the base region 20. The electric field distribution is the electric field distribution in the region along line E3-E3′ of FIG. 26.

In the vertical MOSFET of the eighth embodiment, the film thickness of the cell trench insulating layer 34 at the end portion of the cell trench CT1 is thick as compared with the second comparative example. The film thickness of the cell trench insulating layer 34 at the end portion of the cell trench CT1 is thick in both the first direction and the second direction. The film thickness in the second direction is thicker and accordingly, the cell field plate electrode 32 also has a two-stage field plate structure in the first direction. Accordingly, as compared with the second comparative example, concentration of the electric field at the end portion of the cell trench CT1 is relaxed and avalanche breakdown is prevented. Therefore, the reduction of the breakdown voltage of the vertical MOSFET is prevented.

The distance (e.g., d3 in FIG. 23) between the end portion of the cell trench CT1 and the end portion of the base region 20 is preferably greater than or equal to the distance (e.g., d4 in FIG. 24A) between the base region 20 and the end portion on the side of the rear surface of the semiconductor layer 10 of the cell trench CT1. By satisfying this condition described above, the distance between the end portion of the cell trench CT1 and the base region 20 in the first direction is equal to or greater than the distance between the base region 20 and the bottom of the cell trench CT1. For that reason, the electric field in the lateral direction of the region between the end portion of the cell trench CT1 and the base region 20 in the first direction is relaxed, and the breakdown voltage of the vertical MOSFET is improved.

### Ninth Embodiment

The semiconductor device of a ninth embodiment is different from the eighth embodiment in that a field plate electrode is located between the end portion of each of the trenches and the gate electrode. Hereinafter, descriptions of contents overlapping with the eighth embodiment will be omitted.

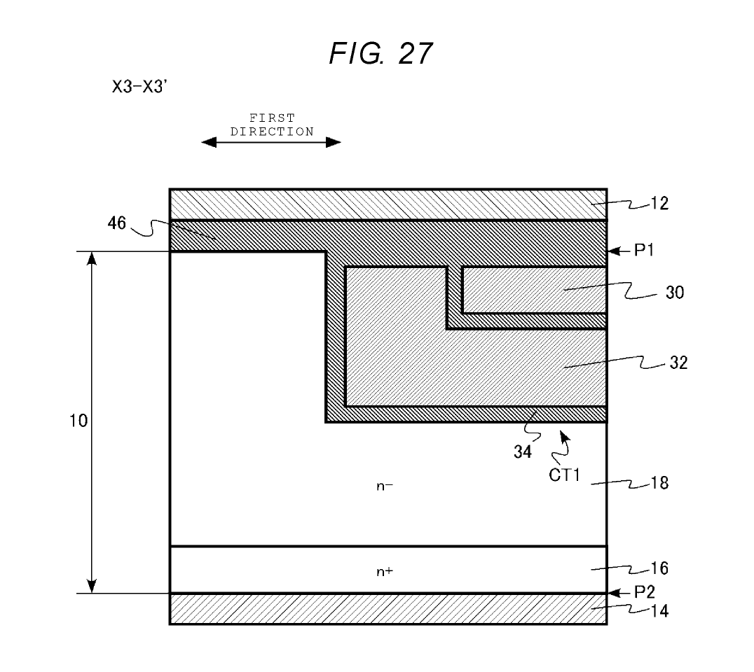

FIG. 27 is a schematic cross-sectional view of a portion of a semiconductor device of a ninth embodiment. FIG. 27 is a cross section corresponding to that depicted in FIG. 25 for the eighth embodiment.

In the vertical MOSFET of the ninth embodiment, the cell field plate electrode 32 is present between the end portion of the cell trench CT1 and the cell gate electrode 30.

For example, when the cell field plate electrode 32 in the cell trench CT1 is formed by an etch-back process, the end portion of the cell trench CT1 and the top of the termination trench TT1 are covered with a mask material to thereby make it possible to form the structure of the ninth embodiment.

In the vertical MOSFET of the ninth embodiment, a region where the cell gate electrode 30 which faces the semiconductor layer 10 via the cell trench insulating layer 34 is not present in the end portion of the cell trench CT1. Accordingly, a parasitic capacitance between a gate and a drain of the vertical MOSFET is reduced. Therefore, a switching speed of the vertical MOSFET is increased.

As described above, according to the vertical MOSFET of the ninth embodiment, it is possible to improve the breakdown voltage of the vertical transistor as in the eighth embodiment. Furthermore, it is possible to improve the switching speed of the vertical transistor.

In the first to ninth embodiments, a case in which the semiconductor layer is single crystal silicon has been described as an example, but the semiconductor layer is not limited to single crystal silicon. For example, semiconductors such as silicon carbide may be used.

In the first to ninth embodiments, a case in which an n-channel type transistor in which the first conductivity type is p-type and the second conductivity type is n-type has been described as an example, but it is also possible to similarly form p-channel type transistors in which the first conductivity type is n-type and the second conductivity type is p-type in other embodiments.

In the first to ninth embodiments, although vertical transistor that is a vertical MOSFET has been described as an example, the vertical transistor may instead be a vertical IGBT.

While certain embodiments have been described, these embodiments have been presented by way of example only, and are not intended to limit the scope of the present disclosure. Indeed, the novel embodiments described herein may be embodied in a variety of other forms; furthermore, various omissions, substitutions and changes in the form of the embodiments described herein maybe made without departing from the spirit of the present disclosure. The accompanying claims and their equivalents are intended to cover such forms or modifications as would fall within the scope and spirit of the present disclosure.

What is claimed is:

1. A semiconductor device, comprising:
a semiconductor layer having a first surface and a second surface opposite the first surface;
a first electrode contacting the first surface;
a second electrode contacting the second surface;
a plurality of first trenches in the semiconductor layer, each first trench extending longitudinally in a first direction that is substantially parallel to the first surface, spaced from an adjacent first trench in the plurality of first trenches in a second direction crossing the first direction and substantially parallel to the first direction, and extending into the semiconductor layer along a third direction substantially orthogonal to the first surface;
a second trench in the semiconductor layer and surrounding the plurality of first trenches within a plane substantially parallel to the first surface;
a first gate electrode in each first trench of the plurality of first trenches;
a first field plate electrode in each first trench of the plurality of first trenches between the first gate electrode and the second surface in the third direction;
a first insulating layer including:
a first portion of a first film thickness in each first trench of the plurality of first trenches between the first gate electrode and the semiconductor layer,
a second portion of a second film thickness in each first trench of the plurality of first trenches between the first field plate electrode and the semiconductor layer, the second film thickness being greater than the first film thickness, and
a third portion of a third film thickness in each first trench of the plurality of first trenches between the second portion and the second surface, the third film thickness being greater than the second film thickness;
a second field plate electrode in the second trench;
a second insulating layer in the second trench between the second field plate electrode and the semiconductor layer;
a first semiconductor region of the semiconductor layer having a first conductivity type and being between two adjacent first trenches of the plurality of first trenches;
a second semiconductor region of the semiconductor layer having a second conductivity type and being between the first semiconductor region and the second surface along the third direction; and
a third semiconductor region of the semiconductor layer having the second conductivity type, the third semiconductor region being between the first semiconductor region and the first electrode along the third direction and electrically connected to the first electrode.

2. The semiconductor device according to claim 1, wherein a minimum distance between the second trench and each first trench of the plurality of first trenches is less than a minimum distance between adjacent first trenches of the plurality of first trenches.

3. The semiconductor device according to claim 2, wherein the minimum distance between the second trench and each first trench of the plurality of first trenches is 90% or less of the minimum distance between adjacent first trenches of the plurality of first trenches.

4. The semiconductor device according to claim 1, wherein a minimum distance along the first direction from an end portion of the first trenches of the plurality of first trenches to an end portion of the first semiconductor region is greater than or equal to a minimum distance from the first semiconductor region to a bottom of the plurality of first trenches along the third direction.

5. The semiconductor device according to claim 1, wherein the first field plate electrode in each first trench is between end portions of each first trench and the first gate electrode in each first trench.

6. The semiconductor device according to claim 1, wherein a film thickness of the first insulating layer continuously decreases along the third direction.

7. The semiconductor device according to claim 1, wherein the first semiconductor region is between an end portion of each first trench of the plurality of first trenches and the second trench.

8. The semiconductor device according to claim 1, further comprising:
a fourth semiconductor region of the semiconductor layer between the second semiconductor region and an end portion of the first semiconductor region, the fourth semiconductor region contacting the first semiconductor region and being of the first conductivity type with an impurity concentration that is lower than an impurity concentration of the first semiconductor region.

9. The semiconductor device according to claim 1, further comprising:
a plurality of third trenches in the semiconductor layer, extending longitudinally in the first direction, and having a length along the first direction that is shorter than a length of the plurality of first trenches along the first direction; and
a fourth trench in the semiconductor layer and surrounding the plurality of third trenches within the plane substantially parallel to the first surface.

10. The semiconductor device according to claim 9, wherein a spacing distance between two adjacent first trenches in the plurality of first trenches is substantially equal to a spacing distance between the second trench and the fourth trench.

11. The semiconductor device according to claim 1, further comprising:
a plurality of third trenches in the semiconductor layer, extending longitudinally in the first direction, and having a length along the first direction that is shorter than a length of the plurality of first trenches along the first direction; and
a fourth trench in the semiconductor layer, extending longitudinally in the first direction, and disposed between the plurality of first trenches and the plurality of third trenches, wherein
the second trench surrounds the plurality of first trenches, the plurality of third trenches, and the fourth trench within the plane substantially parallel to the first surface,
a distance between an end portion of the fourth trench and the second trench is less than a distance between the end portion of each first trench of the plurality of first trenches and the second trench and also less than a distance between an end portion of each third trench of the plurality of third trenches and the second trench.

12. The semiconductor device according claim 1, further comprising:
a gate electrode pad above a first portion of the plurality of first trenches in the third direction, wherein
the first semiconductor region is absent between adjacent first trenches of the first portion below the gate electrode pad and present between adjacent first trenches other than the first portion.

13. The semiconductor device according to claim 1, wherein the second film thickness is 40% to 60% of the third film thickness.

14. The semiconductor device according claim 1, wherein the second insulating layer includes:
a portion having a fourth film thickness between the second field plate electrode and the semiconductor layer, and
a fifth portion between the fourth portion and the second surface and having a fifth film thickness thicker than the fourth film thickness.

15. The semiconductor device according claim 1, further comprising:
a second gate electrode in the second trench, wherein the second field plate electrode is between the second gate electrode and the second surface.

16. A semiconductor device, comprising:
a semiconductor layer having a first surface and a second surface which faces the first surface;
a first electrode contacting the first surface;
a second electrode contacting the second surface;
a plurality of trenches in the semiconductor layer and extending longitudinally in a first direction substantially parallel to the first surface;
a gate electrode in each trench of the plurality of trenches;
a field plate electrode in each trench of the plurality of trenches and between the gate electrode and the second surface;
an insulating layer in each trench of the plurality of trenches and including:
a first portion having a first film thickness between the gate electrode and the semiconductor layer,
a second portion between the field plate electrode and the semiconductor layer and having a second film thickness thicker than the first film thickness,
a third portion between the second portion and the second surface and having a third film thickness thicker than the second film thickness, and
a fourth portion between an end portion of the field plate electrode and the semiconductor layer and having a fourth film thickness thicker than the second film thickness;
a first semiconductor region of the semiconductor layer having a first conductivity type and between two adjacent trenches of the plurality of trenches;
a second semiconductor region of the semiconductor layer having a second conductivity type and between the first semiconductor region and the second surface; and
a third semiconductor region of the semiconductor layer having the second conductivity type and between the first semiconductor region and the first electrode, the third semiconductor region being electrically connected to the first electrode.

17. The semiconductor device according to claim 16, wherein the fourth film thickness is substantially equal to the third film thickness.

18. The semiconductor device according to claim 16, wherein the field plate electrode is between an end portion of each trench of the plurality of trenches and the gate electrode.

19. The semiconductor device according to claim 16, wherein a minimum distance along the first direction from an end portion of each trench of the plurality of trenches to an end portion of the first semiconductor region is greater than or equal to a minimum distance from the first semiconductor region to a bottom of the plurality of trenches.

20. The semiconductor device according claim 16, wherein the second film thickness is 40% to 60% of the third film thickness.
